(19) United States
(12) Patent Application Publication
(10) Pub. No.: US 2025/0311376 A1
(43) Pub. Date: Oct. 2, 2025

(54) COUPLED MULTI-LAYER MAGNETOELECTRIC, FERROELECTRIC, AND FERROMAGNETIC STRUCTURES

(71) Applicant: Intel Corporation, Santa Clara, CA (US)

(72) Inventors: Hai Li, Portland, OR (US); Punyashloka Debashis, Hillsboro, OR (US); Mahendra DC, Portland, OR (US); Ian Alexander Young, Olympia, WA (US); Yu-Ching Liao, Portland, OR (US); Karam Cho, Hillsboro, OR (US); Raseong Kim, Portland, OR (US); John J. Plombon, Portland, OR (US); Marko Radosavljevic, Portland, OR (US); Carly Rogan, North Plains, OR (US); Dominique A. Adams, Portland, OR (US); Jennifer Lux, Hillsboro, OR (US); Tristan A. Tronic, Aloha, OR (US); Christopher M. Gay, Portland, OR (US); Joshua W. Kevek, Portland, OR (US); Scott B. Clendenning, Portland, OR (US)

(73) Assignee: Intel Corporation, Santa Clara, CA (US)

(21) Appl. No.: 18/622,609

(22) Filed: Mar. 29, 2024

(51) Int. Cl. H01L 29/51; H01L 29/82; H10N 50/01; H10N 50/10; H10N 50/85

(52) U.S. Cl. CPC H10D 64/689; H10D 48/40; H10N 50/01; H10N 50/10; H10N 50/85

(57) ABSTRACT

Multi-layer magnetoelectric, ferroelectric, and ferromagnetic structures comprising one or more soft layers and one or more hard layers have a lower coercive voltage than magnetoelectric, ferroelectric, and ferromagnetic structures comprising a single layer. The lower coercive voltage of the overall multi-layer structure is due to exchange coupling between the soft and hard layers. The soft layer has a coercive voltage that is lower than the coercive voltage of the hard layer and magnetic exchange coupling between the soft and hard layers during switching makes it easier for the hard layer to switch polarization or magnetization states. The multi-layer magnetoelectric, ferroelectric, and ferromagnetic structures can be used in a variety of spintronic devices, such as capacitors, magnetoelectric spin-orbit (MESO) devices, magnetoelectric magnetic tunneling junctions (MEMTJs), and ferroelectric field effect transistors (FeFETs).

### BACKGROUND

The coercive voltage of a magnetoelectric, ferroelectric, or ferromagnetic layer—the voltage applied across the layer that causes its electrical polarization or magnetization to switch—depends on the material the layer is made of, its thickness, and temperature. The coercive voltage of these layers can also depend on other factors, such as the processing conditions under which the layer was formed. For layers of these materials having a thickness on the order of hundreds of nanometers, the coercive voltage can be on the order of hundreds of millivolts, thus making them attractive for use in “beyond CMOS” devices, which is an alternative device type being investigated as a possible alternative to electronic transistors.

### BRIEF DESCRIPTION OF THE DRAWINGS

FIG. 1 illustrates a first example capacitor comprising a multi-layer magnetoelectric dielectric.

FIG. 2 illustrates a second example capacitor comprising a multi-layer magnetoelectric dielectric.

FIG. 3 illustrates an example magnetoelectric spin-orbit device that can comprise multi-layer magnetoelectric and/or ferromagnetic structures.

FIG. 4 illustrates an example magnetoelectric magnetic tunnel junction (MEMTJ) device that can comprise multi-layer magnetoelectric and/or ferromagnetic structures.

FIG. 5 illustrates a first example capacitor comprising a multi-layer ferroelectric dielectric.

FIG. 6 illustrates a second example capacitor comprising a multi-layer ferroelectric dielectric.

FIG. 7 illustrates an example ferroelectric field effect transistor (FeFET) that can comprise multi-layer ferroelectric structures.

FIG. 8 illustrates an example method for fabricating a multi-layer magnetoelectric structure.

FIG. 9 illustrates an example method for fabricating a multi-layer ferroelectric structure.

FIG. 10 is a top view of a wafer and dies that may be included in a microelectronic assembly, in accordance with any of the embodiments disclosed herein.

FIG. 11 is a cross-sectional side view of an integrated circuit device that may be included in a microelectronic assembly, in accordance with any of the embodiments disclosed herein.

FIGS. 12A-12D are perspective views of example planar, FinFET, gate-all-around, and stacked gate-all-around transistors.

FIG. 13 is a cross-sectional side view of an integrated circuit device assembly that may include a microelectronic assembly, in accordance with any of the embodiments disclosed herein.

FIG. 14 is a block diagram of an example electrical device that may include a microelectronic assembly, in accordance with any of the embodiments disclosed herein.

### DETAILED DESCRIPTION

Beyond CMOS devices comprising magnetoelectric, ferroelectric, or ferromagnetic layers are an emerging alternative to CMOS (complementary metal-oxide-semiconductor) transistors as the continued scaling of CMOS transistors becomes more challenging. Spintronic devices utilize a physical variable of magnetization (or electron spin) or polarization as a computational variable instead of just electronic charge, as is the case in electronic transistors. Beyond CMOS devices include MESO (magnetoelectric spin-orbit) devices, FeFETs (ferroelectric field effect transistors), and MTJs (magnetic tunnel junctions). The power supply voltage needed to operate devices comprising magnetoelectric, ferroelectric, and ferromagnetic layers can be dependent on their coercive voltage, the voltage that needs to be applied across these layers to cause them to change their magnetization or electrical polarization. While the coercive voltage of some existing and proposed magnetoelectric, ferroelectric, and ferromagnetic layers are on the order of hundreds of millivolts, there is an interest in reducing the coercive voltages of these layers even further to enable devices with ultra-low power supply voltages. Reducing the thickness and tailoring the doping of these layers can enable low coercive voltages and may enable coercive voltages as low as 150 millivolts, but scaling the coercive voltage further may require alternative approaches. For example, at some point in scaling the thickness of magnetoelectric, ferroelectric, and ferromagnetic layers, leakage current across the layer may become a large enough concern that further scaling of the layer thickness is not a practical option.

Described herein are multi-layer structures (or stacks) comprising one or more “soft” and one or more “hard” magnetoelectric, ferroelectric, or ferromagnetic layers. The coercive voltage of the overall structures is less than if the structure were comprised of a single magnetoelectric, ferroelectric, or ferromagnetic layer. The soft and hard layers are positioned next to each other, and the soft layers have a coercive voltage that is lower than the coercive voltage of the hard layers.

The lower coercive voltage of a multi-layer structure is enabled by exchange coupling between the soft and hard layers. During switching in a multi-layer magnetoelectric structure, an external electric field is applied across the structure and is felt by each layer. The electrical polarization of the soft layer tilts first due to the soft layer having a lower coercive voltage. As the electrical polarization of magnetoelectric materials is tightly coupled to their magnetization, the tilting of the electrical polarization affects the soft layer's magnetization. This effect is transferred to the magnetization of the hard layer through exchange coupling. That is, as the magnetization of the soft layer begins to switch due to the tilting of the soft layer's electrical polarization, it becomes easier for the magnetization of the hard layer to switch. The multi-layer structures disclosed herein can be thick enough and/or have sufficient volume such that they have a high enough thermal energy barrier to keep leakage current at low enough levels to enable their use in existing and proposed practical devices. Magnetic exchange coupling between soft and hard ferromagnetic layers can reduce the coercive voltage of multi-layer ferromagnet structures as well.

The technologies described herein have the advantage of enabling magnetoelectric, ferroelectric, and ferromagnetic structures that have low coercive voltages. This can enable devices that have low switching and power supply voltages and low power consumption. Further, the multi-layer structures disclosed herein can have higher switching frequencies relative to single-layer magnetoelectric, ferroelectric, and ferromagnetic structures with higher coercive voltages. This can reduce device, circuit, and/or system latency and enable additional power savings.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact with each other and “coupled” may indicate elements co-operate or interact with each other, but they may or may not be in direct physical or electrical contact. Furthermore, the terms “comprising,” “including,” “having,” and the like, as used with respect to embodiments of the present disclosure, are synonymous.

Terms modified by the word “substantially” include arrangements, orientations, spacings, positions, or values that vary slightly from the meaning of the unmodified term. For example, a first dopant concentration range that substantially non-overlaps with a second dopant concentration can include a first dopant concentration range that has a concentration that overlaps with the second dopant concentration range by several percent. Values modified by the word “about” include values within +/−10% of the listed values and values listed as being within a range include those within a range from 10% less than the listed lower range limit and 10% greater than the listed higher range limit.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

Certain terminology may also be used herein for the purpose of reference only, and thus are not intended to be limiting. For example, terms such as “upper,” “lower,” “above,” “below,” “bottom,” and “top” refer to directions in the Figures to which reference is made. Terms such as “front,” “back,” “rear,” and “side” describe the orientation and/or location of layers, components, portions of components, etc., within a consistent but arbitrary frame of reference, which is made clear by reference to the text and the associated Figures describing the layers, component, portions of components, etc. under discussion. Such terminology may include the words specifically mentioned above, derivatives thereof, and words of similar import.

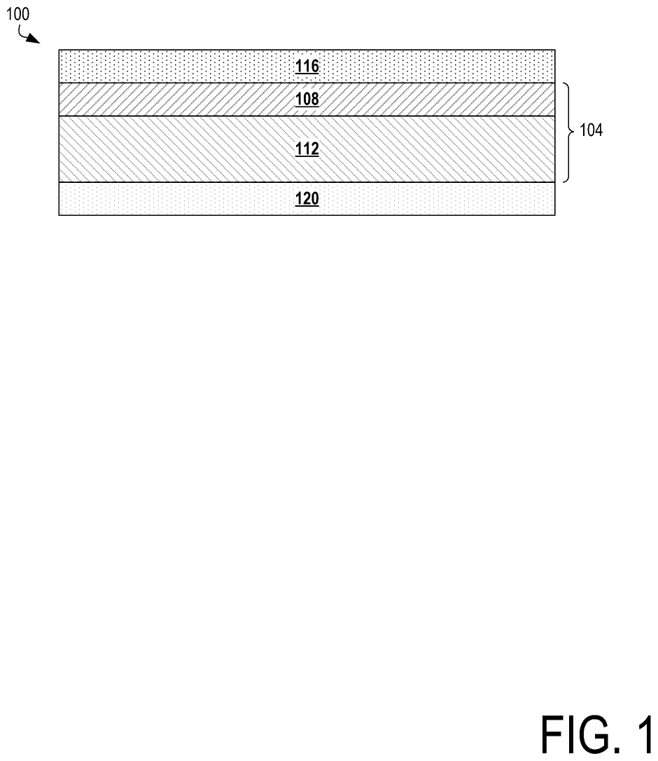

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components. For example, with reference to FIG. 1, soft magnetoelectric layer 108 is located on bottom electrode 120 with intervening hard magnetoelectric layers 112.

As used herein, the term “integrated circuit component” refers to a packaged or unpacked integrated circuit product. A packaged integrated circuit component comprises one or more integrated circuit dies mounted on a package substrate with the integrated circuit dies and package substrate encapsulated in a casing material, such as a metal, plastic, glass, or ceramic. In one example, a packaged integrated circuit component contains one or more processor units mounted on a substrate with an exterior surface of the substrate comprising a solder ball grid array (BGA). In one example of an unpackaged integrated circuit component, a single monolithic integrated circuit die comprises solder bumps attached to contacts on the die. The solder bumps allow the die to be directly attached to a printed circuit board is an integrated circuit component can comprise one or more of any computing system component described or referenced herein or any other computing system component, such as a processor unit (e.g., system-on-a-chip (SoC), processor core, graphics processor unit (GPU), accelerator, chipset processor), I/O controller, memory, or network interface controller.

Reference is now made to the drawings, which are not necessarily drawn to scale, wherein similar or same numbers may be used to designate same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

FIG. 1 illustrates a first example capacitor comprising a multi-layer magnetoelectric structure. The capacitor 100 comprises a multi-layer magnetoelectric structure 104 (magnetoelectric stack) positioned between a top electrode 116 and a bottom electrode 120. The magnetoelectric structure 104 comprises a soft magnetoelectric layer 108 and a hard magnetoelectric layer 112. As discussed above, the soft magnetoelectric layer 108 has a coercive voltage that is lower than the coercive voltage of the hard magnetoelectric layer 112.

The coercive voltage of the soft and hard magnetoelectric layers 108 and 112 can based on various factors, such as layer thickness, the material that makes up the layer, and the processing conditions under which the magnetoelectric layer was formed. The coercive voltage can also depend on operating temperature. FIG. 1 illustrates the thickness of the soft magnetoelectric layer 108 as being less than the thickness of the hard magnetoelectric layer 112, but in other embodiments, the soft magnetoelectric layer 108 can have a thickness that is substantially the same or greater than the thickness of the hard magnetoelectric layer 112. A soft magnetoelectric layer that is as thick as or thicker than a hard magnetoelectric layer can still have a lower coercive voltage than the hard magnetoelectric layer due to other characteristics of the soft magnetoelectric layer, such as material composition. In some embodiments, the thickness of the magnetoelectric stack 104 can be about or less than 10 nanometers or another value.

The soft and hard magnetoelectric layers 108 and 112 can comprise the same or different magnetoelectric materials. In some embodiments, the soft and hard magnetoelectric layers 108 and 112 can comprise the same materials, but with a dopant present in one of the layers. In some embodiments, the soft and hard magnetoelectric layers 108 and 112 can comprise the same materials but have different dopant concentrations. For example, the concentration of a dopant in one of the magnetoelectric layers 108 and 112 can be in a first concentration range and the concentration of the dopant in the other of the magnetoelectric layers 108 and 112 can be in a second concentration range. In some embodiments, the first and second concentration ranges can be substantially non-overlapping, and in other embodiments, the maximum concentration of the first concentration range can be less than the minimum concentration of the second concentration range.

The soft and hard magnetoelectric layers 108 and 112 can comprise any suitable magnetoelectric materials, such as bismuth ferrite (BiFeO₃, also referred to as BFO, which is a material that comprises bismuth, iron, and oxygen), samarium-doped bismuth ferrite (Sm-doped BiFO₃, which is a material that comprises bismuth, iron, oxygen, and samarium), lanthanum-doped bismuth ferrite (La-doped BiFO₃, which is a material that comprises bismuth, iron, oxygen, and lanthanum), lutetium ferrite (LuFeO₃, also referred to LFO, which is a material that comprises lutetium, iron, and oxygen), barium titanate (BaTiO₃, also known as BTO, a material that comprises barium, titanium, and oxygen), lead zirconate titanate (Pb(ZrₓTi₁₋ₓ)O₃, also known as PZT, which is a material that comprises lead, zirconium, and titanium), lead magnesium niobate-lead titanate (Pb(Mg_{1/3}Nb_{2/3})O₃—PbTiO₃, also known as PMN-PT, which is a material that comprises lead, manganese, niobium, titanium, and oxygen), chromium oxide (Cr₂O₃, a material that comprises chromium and oxygen), boron-doped chromium oxide (e.g., Cr₂O₃ doped with boron), TbMnO₃ (a material comprising terbium, manganese, and oxygen), Fe₃Ga (a material comprising iron and gallium), TbₓDy₁₋ₓFe₂ (a material comprising terbium, dysprosium, and iron), FeRh (a material comprising iron and rhodium), Fe₂TeO₆ (a material comprising iron, tellurium, and oxygen).

In some embodiments, the soft and hard magnetoelectric layers 108 and 112 comprise any magnetoelectric perovskites. Perovskites are materials that have the general chemical formula of ABX₃ and comprise mostly oxides (X=oxygen). Perovskites have the same lattice structure and similar lattice constants. In other embodiments, the soft magnetoelectric layer 108 can comprise PZT or PMN-PT and the hard magnetoelectric layer 112 can comprise PZT or PMN-PT.

In some embodiments, the top and bottom electrodes 116 and 120 can comprise a metal, alloy, or other suitable conductor, such as copper, aluminum, cobalt, tungsten, tantalum, nickel, molybdenum, titanium, nickel, or graphene.

While FIG. 1 illustrates an embodiment in which a magnetoelectric stack comprises two magnetoelectric layers—one soft, one hard—in other embodiments, a multi-layer magnetoelectric structure having a low coercive voltage can comprise more than two magnetoelectric layers.

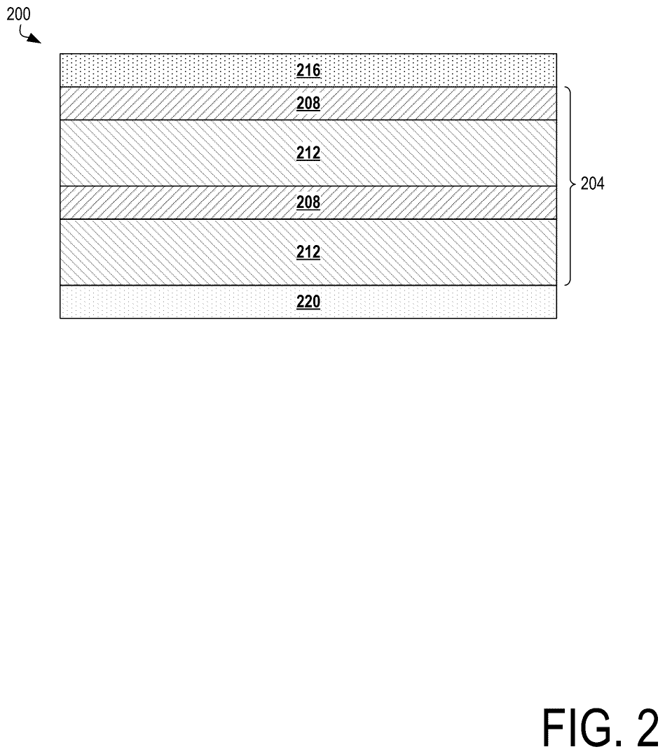

FIG. 2 illustrates a second example capacitor comprising a multi-layer magnetoelectric structure. The structure 200 comprises a magnetoelectric stack 204 comprising a pair of soft magnetoelectric layers 208 interleaved with a pair of hard magnetoelectric layers 212. The magnetoelectric stack 204 is positioned between a top electrode 216 and a bottom electrode 220. The magnetoelectric layers 208 and 212 can comprise any of the magnetoelectric layers described herein and the top and bottom electrodes can comprise any electrode or any other layer that can be located on or positioned next to a magnetoelectric layer as described herein. While FIG. 2 illustrates two soft magnetoelectric layers 208 and two hard magnetoelectric layers 212, in other embodiments, the magnetoelectric stack 204 can comprise any number of interleaving soft and hard magnetoelectric layers. Further, in some embodiments, a magnetoelectric stack can comprise an uneven number of layers with the top and bottom magnetoelectric layers in the magnetoelectric stack 204 being soft magnetoelectric layers or hard magnetoelectric layers.

While the multi-layer magnetoelectric structures 104 and 204 are illustrated as being part of capacitors, multi-layer magnetoelectric structures can be utilized in other types of devices, such as MESO devices and MEMTJs (magnetoelectric MTJs).

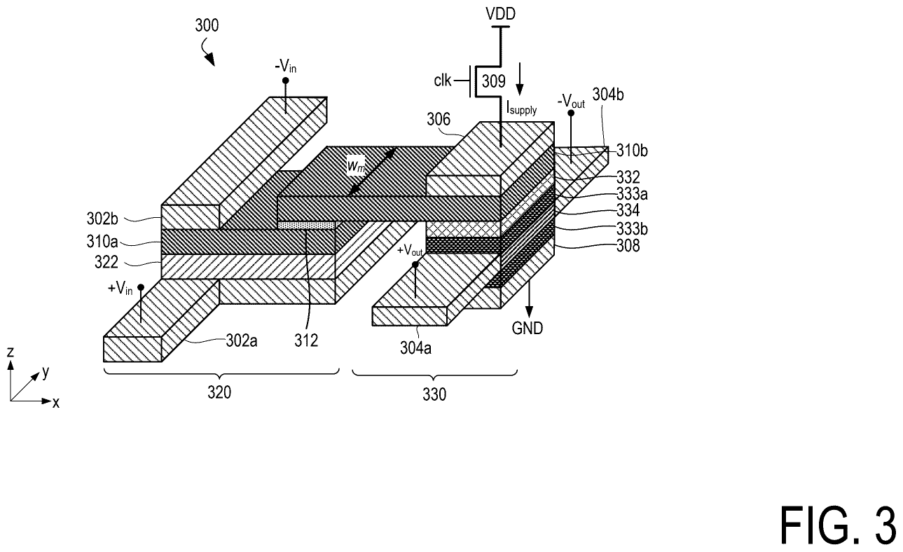

FIG. 3 illustrates an example magnetoelectric spin-orbit device that can comprise multi-layer magnetoelectric and/or ferromagnetic structures. Magnetoelectric spin-orbit (MESO) devices use magnetoelectric switching to convert an input charge/voltage into a magnetic spin state (e.g., charge-to-spin conversion) and spin-orbit transduction to convert the magnetic spin state back into an output charge/voltage (e.g., spin-to-charge conversion). In this manner, a MESO device can be used to implement a logic device with a non-volatile logical state. For example, a logical state represented by an input charge/voltage can be converted into a (non-volatile) magnetic spin state, and the logical state can subsequently be read out by converting the magnetic spin state back into an output charge/voltage. Accordingly, MESO devices can be used to implement logic circuitry (e.g., logic switches/gates) for scalable integrated circuits, analogous to CMOS (complementary metal-oxide-semiconductor) transistors.

MESO device 300 is a differential MESO device. The MESO device 300 comprises a ferromagnet 310, a magnetoelectric conversion module 320, and a spin-orbit conversion structure 330. MESO device 300 also comprises conductive traces (interconnects), portions of which serve as electrodes, to provide differential voltage inputs (+/−Vᵢₙ), a power supply (V_{DD}), and ground (GND) 308, and carry differential voltage outputs (+/−Vₒᵤₜ). For example, conductive traces 302a-b provide differential input voltages (+/−Vᵢₙ), conductive traces 304a-b carry differential output voltage signals (+/−Vₒᵤₜ), conductive trace 306 provides power (V_{DD}), and conductive trace 308 provides ground (GND) to the MESO device 300.

The magnetoelectric module 320 performs charge-to-spin conversion to convert an electric charge current into spin (e.g., inducing a particular direction of magnetization on the ferromagnet 310), and the spin-orbit conversion structure 330 performs spin-to-charge conversion to convert spin (e.g., the direction of magnetization induced on the ferromagnet 310) back into an electric charge current, as described further below.

The ferromagnet 310 is formed by two ferromagnets 310a-b coupled via an inter-magnet insulating layer 312, which collectively function as a single ferromagnet 310. That is, when the magnetization changes on one of the ferromagnets 310a-b, the magnetization orientation on the other ferromagnet changes. The individual ferromagnets 310a and 310b can be any of the multi-layer ferromagnetic structures disclosed herein or be a single layer of ferromagnetic material.

The magnetoelectric module 320 comprises a stack of layers configured to convert an electric charge current into spin (e.g., magnetization). The magnetoelectric module 320 is formed by the positive input voltage (+Vᵢₙ) conductive trace 302a, which in turn is coupled to a magnetoelectric structure 322, which in turn is coupled to ferromagnet 310a, which in turn is coupled to the negative input voltage (−Vᵢₙ) interconnect 302b. The magnetoelectric material can be switched under the application of an external electric field. In this manner, the magnetoelectric module 320 is configured as a capacitor, with ferromagnet 310 and input voltage interconnect 302a serving as electrical plates surrounding the magnetoelectric structure 322. The magnetoelectric structure 322 can be any magnetoelectric stack comprising soft and hard magnetoelectric layers described herein or be a single layer of magnetoelectric material.

When voltage is applied via the differential voltage inputs (+/−Vᵢₙ), charge current (Iᵢₙ) flows across the magnetoelectric structure 322, which results in ferroelectric polarization switching along the electric field in the +/−Z direction depending on the polarity of the current (Iᵢₙ). Spin magnetization will tightly couple with polarization and switch together. As the surface spin magnetization is formed, it becomes exchange field coupled with ferromagnet 310a, causing the magnetization in ferromagnet 310a to align with the magnetization in the magnetoelectric structure 322. In this manner, the orientation of the magnetization of the ferromagnet 310 can be switched based on the input current (Iᵢₙ). This setting of the orientation of the magnetization of the ferromagnet 310 affects the output of the spin-orbit conversion structure 330, as described below.

The spin-orbit conversion structure 330 is configured to convert spin (e.g., the magnetization) back into an electric charge current. The spin-orbit structure 330 includes a power supply (V_{DD}) conductive trace 306 coupled to ferromagnet 310b, which in turn is coupled to a tunneling barrier 332. Tunneling barrier 332 is coupled to a first spin coherent layer 333a, which in turn is coupled to spin-orbit coupling layer 334, which in turn is coupled to a second spin coherent layer 333b. Ground conductive trace 308 is coupled to the second spin coherent layer 333b. Moreover, in some embodiments, the supply of power to the ferromagnet 310b is controlled via a transistor 309 that has its gate terminal connected to a clock signal or other control signal.

When voltage is applied via the power supply (V_{DD}) conductive trace 306 (e.g., 300 mV), a supply charge current (I_{supply}) flows through ferromagnet 310b. The magnetization of the ferromagnet 310b produces a spin polarized current in which a substantial majority (e.g., greater than 80%) of electrons associated with the supply charge current (I_{supply}) will exhibit spin (e.g., magnetization) having an orientation corresponding to the magnetization of ferromagnet 310b. The strength of the spin polarized current (e.g., the proportion of electrons that align with ferromagnet 310b) is proportional to the strength of the magnetization.

After the supply current passes through ferromagnet 310b and becomes a spin polarized current, the spin polarized current enters the tunneling barrier 332, which serves as a tunneling barrier to the spin-orbit coupling layer 334. For example, because the ferromagnet 310b has low resistance and the spin-orbit coupling layer 334 has high resistance, if those components are adjacent to each other, spin current can flow from the spin-orbit coupling layer 334 back into the ferromagnet 310b. As a result, the tunneling barrier 332 is placed between the ferromagnet 310b and the spin-orbit coupling layer 334, which serves as a tunneling barrier to prevent spin flow from the spin-orbit coupling layer 334 back into the ferromagnet 310b. In this manner, the spin polarized current flows from ferromagnet 310b through the tunneling barrier 332 and into the spin-orbit coupling layer 334, with a small amount or no spin flow in the opposite direction. The spin coherent layer 333a can further improve the spin polarization of electrons injected into the spin-orbit coupling layer 334. The thickness of the spin coherent layer 333a is less than λ_{sf}, the length of relaxation of spin polarization.

The spin-orbit coupling layer 334 has a strong or high spin-orbit effect, which is referred to as spin-orbit coupling. As a result, when the spin polarized current flows through the spin-orbit coupling layer 334, due to the inverse spin-orbit coupling effect, the spin current converts into charge current (Iₒᵤₜ), which produces an output voltage on the differential output conductive traces (+/−Vₒᵤₜ) 304a-b. A spin coherent layer 334 is coupled to the spin-orbit coupling layer 334 and the output conductive traces 304a-b.

This phenomenon is referred to as the inverse spin Hall effect (SHE), where a spin current transforms into a charge current when the spin current flows through a material with high spin-orbit interaction. By contrast, the standard spin Hall effect is a phenomenon where a charge current transforms into a spin current when the charge current flows through a material with high spin-orbit interaction. The directions of the spins are opposite at opposing lateral boundaries of the material, and the spin polarization is proportional to the current and changes sign when the direction of the current is reversed. Thus, the inverse spin Hall effect is simply the reverse of the spin Hall effect.

In the illustrated example, the spin-orbit structure 330 is configured so that the direction of deflection of the electrons due to the spin Hall effect is either into or away from the differential voltage output conductive traces (+/−Vₒᵤₜ) 304a-b, which serve as an output of the MESO device 300. More particularly, the deflection of electrons produced by the spin Hall effect is along an axis (e.g., the Y-axis) substantially perpendicular to both the supply charge current (I_{supply}) (e.g., the Z-axis) and the spin polarized current corresponding to the orientation of magnetization (e.g., the X-axis), the two of which are substantially perpendicular to each other. Thus, the differential voltage outputs (+/−Vₒᵤₜ) 304a-b are positioned substantially perpendicular to ferromagnet 310b (and associated orientation of magnetization) and substantially perpendicular to the direction of the supply charge current (I_{supply}). Thus, the spin-orbit coupling layer 334 deflects a majority of electrons into or away from the voltage outputs (+/−Vₒᵤₜ) 304a-b, thereby resulting in an output current (Iₒᵤₜ) that is proportional to the supply charge current (I_{supply}). In this manner, an output voltage is produced on the differential voltage output conductive traces (+/−Vₒᵤₜ) 304a-b, which serves as an output of the MESO device 300. A residual current may also pass through the spin-orbit coupling layer 334 to ground conductive trace 308.

In the illustrated example, the input voltage differential (+/−Vᵢₙ) and the supply charge current (I_{supply}) may be provided during separate operations implemented at different times. More particularly, providing the input voltage differential may be compared to a write operation that sets or adjusts the orientation of the magnetization of the ferromagnet 310. Further, providing the supply charge current (I_{supply}) may be compared to a read operation that produces the output voltage differential (+/−Vₒᵤₜ), which is proportional to the magnetization of the ferromagnet 310 previously established during the write operation associated with the input voltage (Vᵢₙ).

In some embodiments, the MESO device of FIG. 3 is a perovskite-based MESO device in that perovskite materials are used for the conductive traces 302a-b, 304a-b, 306, and 308, the magnetoelectric structure 322, the ferromagnets 310a-b, the inter-magnet insulating layer 312, the tunneling barrier 332, the spin coherent layers 333a-b, and the spin-orbit coupling layer 334.

MESO conductive traces carrying or providing input signals, output signals, power, and ground (e.g., 302a-b, 304a-b, 306, and 308), and interconnects connecting to these conductive traces can comprise suitable perovskite materials, such as lanthanum strontium manganite (La₍₁₋ₓ₎Sr₍ₓ₎MnO₃, also known as LSMO, a material comprising lanthanum, strontium, manganese, and oxygen)), niobium-doped strontium titanate (Nb—SrTiO₃, also known as Nb-STO, a material comprising niobium, strontium, titanium, and oxygen), and/or SrRuO₃ (also known as SRO, a material comprising strontium, ruthenium, and oxygen).

The ferromagnets 310a-b can comprise suitable perovskite materials, such as LSMO and La₍₁₋ₓ₎Sr₍ₓ₎Fe_{(1-y)}Mo_{(y)}O₃ (also known LSFMO, a material comprising lanthanum, strontium, iron, molybdenum, and oxygen), LSMO, or Co-doped or Fe-doped perovskite oxides (e.g., CaTiO₃). The inter-magnet insulating layer 312 can comprise a suitable perovskite insulator, such as WO₃, NaTaO₃, SrTiO₃, BaTiO₃, KTaO₃, and LiNbO₃. The tunneling barrier 332 can comprise a suitable perovskite material, such as LaAlO₃. WO₃, NaTaO₃, SrTiO₃, BaTiO₃, KTaO₃, LiNbO₃. The spin coherent layers 333a-b can comprise a suitable perovskite material, such as SrTiO₃, SrRuO₃, or CaMnO₃. The spin-orbit coupling layer 334 can comprise a single layer of suitable perovskite material, such as SrIrO₃ or BaIrO₃.

In MESO device embodiments where not all MESO device layers comprise perovskites, the ferromagnets 310a-b can comprise any suitable magnetic or ferromagnetic non-perovskite material, including, cobalt iron (CoFe), CoFeB, and nickel iron (NiFe).

FIG. 3 illustrates just one MESO device structure. Multi-layer magnetoelectric stacks can be utilized in variations of the MESO device illustrated in FIG. 3 and other MESO device structures.

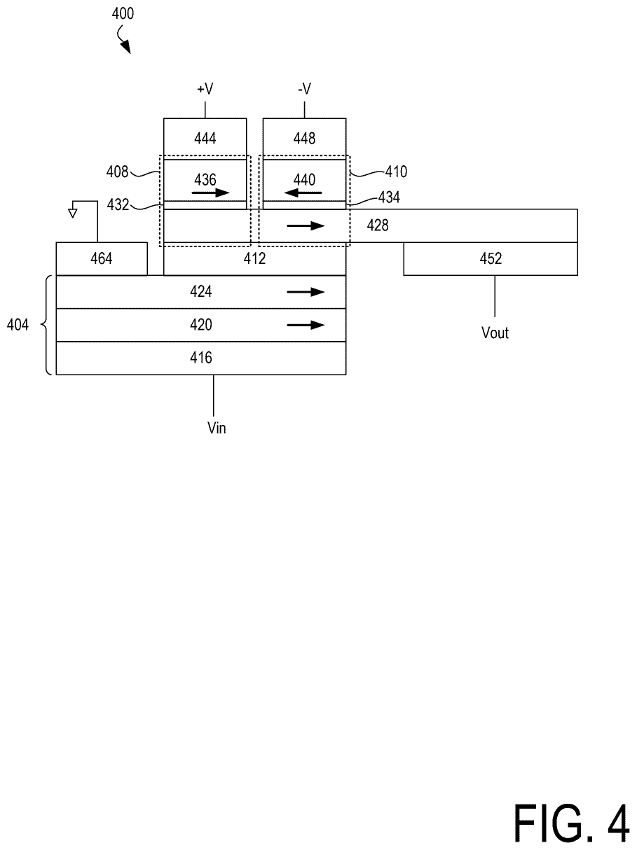

FIG. 4 illustrates an example magnetoelectric magnetic tunnel junction (MEMTJ) device that can comprise multi-layer magnetoelectric and/or ferromagnetic structures. MEMTJs comprise a magnetoelectric switching capacitor coupled to a pair of magnetic tunnel junctions (MTJs) for reading out the logic state of the MEMTJ. The MEMTJ has the low switching energy of a MESO device and a strong enough output signal to switch the logic state of another MEMTJ device. As such, MEMTJs may be usable as logic gates in cascading logic.

The MEMTJ 400 comprises a magnetoelectric switching capacitor 404 coupled to a pair of magnetic tunnel junctions (MTJs) 408 and 410 by an insulating layer 412. The magnetoelectric switching capacitor 404 comprises an electrode 416, a ferromagnet 424, and a magnetoelectric structure 420 positioned between and adjacent to the electrode 416 and the ferromagnetic 424. The MTJ 408 comprises a free ferromagnet 428 that is common to MTJs 408 and 410, a reference ferromagnet 436, and an insulating layer 432 positioned between and adjacent to the ferromagnets 428 and 436. The second MTJ 410 comprises the free ferromagnet 428, a reference ferromagnet 440, and an insulating layer 434 positioned between and adjacent to the ferromagnets 428 and 440. The insulating layers 432 and 434 are tunneling barriers that provide a magnetoresistance to the MTJs, a change in resistance in response to the relative magnetization orientations of the surrounding ferromagnets. The insulating layer 412 is positioned between and adjacent to the ferromagnets 424 and 428. Power supply voltages (+V, −V) are provided to the MTJs 408 and 410 by electrodes 444 and 448 positioned adjacent to the reference ferromagnets 436 and 440, respectively. An electrode 452 is positioned adjacent to the ferromagnet 428. The electrode 416 of the magnetoelectric capacitor acts as the input to the MEMTJ 400 and the electrode 452 acts as the output of the MEMTJ 400. The ferromagnet 424 is tied to ground via an electrode 464 positioned adjacent to the ferromagnet 424.

The logic state of the MEMTJ 400 is switched by establishing a voltage differential across a magnetoelectric structure 420 that has the polarity and sufficient magnitude to cause the magnetization orientation of the ferromagnet 424 to switch. With the potential of the ferromagnet 424 set to ground, application of a positive voltage (Vin) to the electrode 416 causes the orientation of the magnetization of the ferromagnet 424 to be set to a first orientation and the MEMTJ to be set to a first logic state. Application of a negative voltage to the input electrode 416 causes the magnetic orientation of the ferromagnet 424 to be set to a second orientation that is substantially opposite to that of the first orientation and the MEMTJ to be set to a second logic state.

The MEMTJ 400 switches logic state as follows. Application of a positive voltage differential across the magnetoelectric switching capacitor 404 causes the polarization of the magnetoelectric structure 420 to point downward. As the magnetoelectric structure 420 is a multiferroic layer that is antiferromagnetic as well as magnetoelectric, the magnetization vector of the magnetoelectric structure 420 will become oriented horizontally rightward (the arrows in FIG. 4 illustrate the orientation of the magnetization vector in various layers in response a positive input voltage applied to the input electrode 416). The magnetization of the magnetoelectric structure 420 is coupled to the magnetization of the ferromagnet 424 through exchange bias and, if the magnitude of potential difference applied across the magnetoelectric capacity is large enough, becomes oriented horizontally rightward as well. The insulating layer 412 is a ferromagnet and an electrical insulator. The magnetic coupling between the ferromagnets 424 and 428 provided by the ferromagnetism of the insulating layer 412 provides for the magnetization of the ferromagnet 428 to switch with that of ferromagnetic 424, and the electrical insulation provided by the insulating layer 412 reduces electrical interference between the magnetoelectric capacitor 404 and the MTJs 408 and 410. Thus, ferromagnets 424 and 428 are electrically isolated but effectively switch magnetically as a single magnet. In a similar fashion, application of a negative input voltage having sufficient magnitude to the input electrode 416 of the MEMTJ can cause the magnetization orientation of the ferromagnets 424 and 428 to be set leftward.

Thus, the two logic states of the MEMTJ are represented by the leftward and rightward orientation of the magnetization of the ferromagnets 436 and 440. The MTJs 408 and 410 convert the magnetization orientation of the ferromagnet 428 into an output voltage by selectively providing a low resistance path between the electrode 452 and one of the ferromagnets 436 and 440. In an MTJ, the insulating layer between the two ferromagnets is an electrically insulating and non-magnetic layer that is thin enough to allow for electrons to tunnel between the two ferromagnets. The magnitude of the tunneling current and hence the resistance of the MTJ is dependent on the relative magnetization of the two ferromagnets comprising an MTJ. The tunneling current is greater (and the MTJ resistance is less) if the magnetization orientations of the two ferromagnets are parallel and the tunneling current is less (and the MTJ resistance greater) if the magnetization orientations of the ferromagnets are anti-parallel.

To selectively provide a low resistance path between the output electrode 452 and one of the MTJ reference ferromagnets 436 and 440, the magnetization of the reference ferromagnets 436 and 440 are oriented in substantially opposite orientations, as indicated by the arrows in FIG. 4. The ferromagnets 436 and 440 are reference ferromagnets in that their magnetization orientation does not change in response to the switching of the magnetization orientation of the free ferromagnet 428. The higher stability of the reference ferromagnets 436 and 440 is measured by their coercive fields, the external magnetic field necessary to switch the orientation of their magnetization.

With the reference ferromagnet 436 having a rightward magnetization orientation and the reference ferromagnet 440 having a leftward magnetization orientation, when the magnetization of the ferromagnet 428 is oriented rightward, the MTJ 408 is in its low resistance state and the MTJ 410 is in its high resistance state and the potentials of the ferromagnet 428 and the output electrode 452 are a function of +V, the supply voltage supplied to the electrode 444 of MTJ 408. When the magnetization of the ferromagnet 428 is oriented leftward, the MTJ 408 is in its high resistance state and the MTJ 410 is in its low resistance state and the potentials of the ferromagnet 428 and the output electrode 452 are a function of −V, the supply voltage supplied to the electrode 448 of the MTJ 410.

The magnetoelectric structure 420 can be any multi-layer magnetoelectric stack comprising soft and hard magnetoelectric layers described herein or a single magnetoelectric layer.

The ferromagnets 424, 428, 436, and 440 can be any of the multi-layer ferromagnetic structures disclosed herein or be a single layer of ferromagnetic material. In some embodiments, the ferromagnets 424 and 428 are multi-layer ferromagnet structures and ferromagnets 436 and 440 are single-layer ferromagnets. A layer of a multi-layer ferromagnet structure or a single-layer ferromagnet can comprise any suitable conducting ferromagnetic material, such as cobalt, iron, nickel, or an alloy of conducting ferromagnetic material, such as CoFe, CoFeB, and NiFe, as well as ferromagnetic oxides, such as strontium iron molybdenum oxide (Sr₂FeMoO₆, also known as SFMO, which is a material comprising strontium, iron, molybdenum, and oxygen), strontium chromium rhenium oxide (Sr₂CrReO₆, also known as SCRO, which is a material comprising strontium, chromium, rhenium, and oxygen), LSMO, and magnetite (Fe₃O₄, which is a material comprising iron and oxygen). In some embodiments where the magnetoelectric layer is BiFeO₃, the input electrode 416 comprises a material comprising strontium (Sr), ruthenium (Ru), and oxygen, such as SrRuO₃ (SRO), which can provide for better growth of BiFeO₃ during MEMTJ fabrication.

The insulating layer 412 can comprise a ferrimagnetic material, such as a material that comprises, for example, ytterbium (Yb), iron, oxygen, nickel, cobalt (Co), titanium (Ti), magnesium (Mg), aluminum (Al), zinc (Zn), barium (Ba), strontium (Sr), and/or europium (Eu), such as ytterbium iron garnet (Yb₃Fe₂(FeO₄)₃, Yb₃Fe₅O₁₂), (Ni,Co)₁₊₂ₓTi₁₋ₓO₃, MgAl_{0.5}Fe_{1.5}O₄ (MAFO), NiAlₓFe₂₋ₓO₄ (NAFO), a spinel ferrite such as Fe₃O₄, CoFe₂O₄, EuO, Fe₂O₃, Co₂O₃, Co₂FeO₄, Ni₂FeO₄, or a hexagonal ferrite having the general chemical formula AₓMe_{y}Fe_{z}Oᵢ (where A can be Ba or Sr and Me can be Co²⁺, Ni²⁺ or Zn²⁺), such as BaFe₁₂O₁₉.

In some embodiments, the MTJ insulating layers 432 and 434 comprise a material comprising magnesium, aluminum and/or oxide, such as magnesium oxide (MgO) or aluminum oxide (Al₂O₃).

In some embodiments, the individual electrodes 416, 444, 448, 452, and 464 can be any suitable material, such as copper, aluminum, or another conductive material. In some embodiments, the MTJ electrodes 444 and 448 can comprise a stack of one or more layers with individual layers comprising ruthenium or tantalum. In other embodiments, the MTJ electrodes 444 and 448 can comprise one or more a stack of one or more layers with individual layers comprising tantalum or tungsten.

Thus, with reference to FIGS. 1 and 2, in addition to a magnetoelectric stack being positioned between capacitor electrodes, the magnetoelectric stacks disclosed herein can be positioned between other types of layers or materials. For example, with reference to FIGS. 3 and 4, a magnetoelectric structure (322, 420) can be positioned between an electrode (302a, 416) and a ferromagnet (310a, 424).

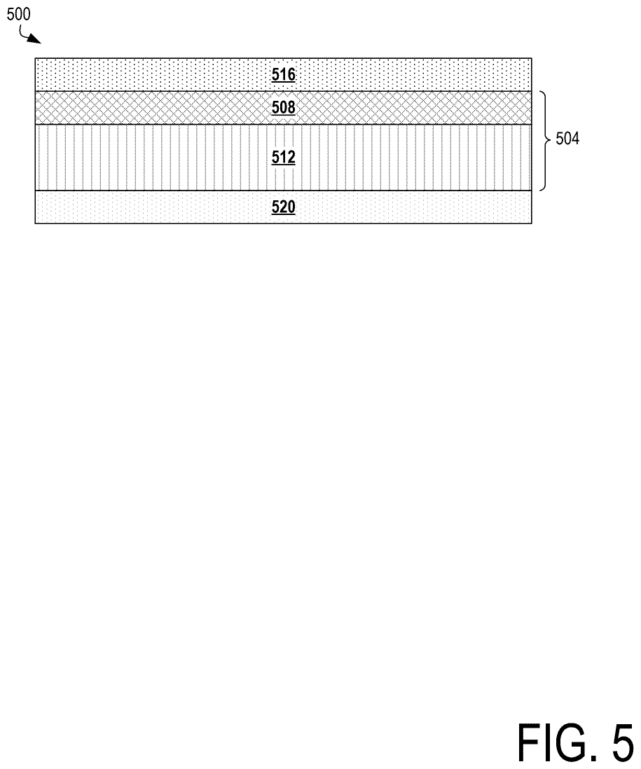

FIG. 5 illustrates a first example capacitor comprising a multi-layer ferroelectric structure. The capacitor 500 comprises a multi-layer ferroelectric structure 504 (ferroelectric stack) positioned between a top electrode 516 and a bottom electrode 520. The ferroelectric structure 504 comprises a soft ferroelectric layer 508 and a hard ferroelectric layer 512. The soft ferroelectric layer 508 has a coercive voltage that is lower than the coercive voltage of the hard ferroelectric layer 512.

The coercive voltage of the soft and hard ferroelectric layers 508 and 512 can be based on various factors, such as layer thickness, the material that makes up the layer, the processing conditions under which the ferroelectric layer was formed, and operating temperature. FIG. 5 illustrates the thickness of the soft ferroelectric layer 508 as being less than the thickness of the hard ferroelectric layer 512, but in other embodiments, the soft ferroelectric layer 508 can have a thickness that is substantially the same or greater than the thickness of the hard ferroelectric layer 512. A soft ferroelectric layer that is as thick as or thicker than a hard ferroelectric layer can still have a lower coercive voltage than the hard ferroelectric layer due to other characteristics of the soft ferroelectric layer, such as material composition. In some embodiments, the thickness of the ferroelectric stack 504 can be about or less than 10 nanometers or another value.

The soft and hard ferroelectric layers 508 and 512 can comprise the same or different materials. In some embodiments, the soft and hard ferroelectric layers 508 and 512 can comprise the same materials, but with a dopant present in one of the layers. In some embodiments, the soft and hard ferroelectric layers 508 and 512 can comprise the same materials but have different dopant concentrations. For example, the concentration of a dopant in one of the ferroelectric layers 508 and 512 can be in a first concentration range and the concentration of the dopant in the other of the ferroelectric layers 508 and 512 can be in a second concentration range. In some embodiments, the first and second concentration ranges can be substantially non-overlapping and in other embodiments, a maximum concentration of the first concentration range can be less than the minimum concentration of the second concentration range.

The soft and hard ferroelectric layers 508 and 512 can comprise suitable ferroelectric material, such as, BTO, BFO, samarium-doped BFO (Sm-doped BFO), lanthanum-doped BFO (La-doped BFO), barium strontium titanate ((Ba,Sr)TiO₃, which is a material comprising barium, strontium, and titanium), lithium tantalate (LiTaO₃, which is a material comprising lithium, tantalum, and oxygen), lead strontium titanate (Pb₁₋ₓSrₓTiO₃, also known as PST, which is a material comprising lead, strontium, titanium, and oxygen), PZT, lead lanthanum zirconate titante ((Pb,La)(Zr,Ti)O₃, also known as PLZT, which is a material comprising lead, lanthanum, zirconium, titanium and oxygen), lead nickel zirconate titanate ((Pb,Ni)(Zr,Ti)O₃, also known as PNZT, which is a material comprising lead, nickel, zirconium, titanium, and oxygen), sodium tantalate (NaTaO₃, which is a material comprising sodium, tantalum, and oxygen), strontium titanate (SrTiO₃, also known as STO, which is a material comprising strontium, titanium, and oxygen), potassium tantalate (KTaO₃, also known as KTO, which is a material comprising potassium, tantalum, and oxygen), lithium tantalate (LiTaO₃, also known as LTO, which is a material comprising lithium, tantalum, and oxygen), bismuth iron cobalt oxide (BiFe₁₋ₓCoₓO₃, which is a material comprising bismuth, iron, cobalt, and oxygen), potassium niobate (KNiO₃, which is a material comprising potassium, niobium, and oxygen), calcium niobium titanate (CaNbTi₂O₆, which is a material comprising calcium, niobium, titanium, and oxygen), lead bismuth niobate (Pb₂BiNbO₆, which is a material comprising lead, bismuth, niobium, and oxygen), calcium niobium nitride oxide (Ca₃Nb₂N₂O₅, which is a material comprising calcium, niobium, nitrogen, and oxygen), bismuth titanate (Bi₄Ti₃O₁₂, which is a material comprising bismuth, titanium, and oxygen), barium hafnium titanium oxide (Ba(Hf,Ti)O₃, which is a material comprising barium, hafnium, titanium, and oxygen), barium calcium zirconium titanium oxide (Ba,Ca)(Zr,Ti)O₃ (which is a material comprising barium, calcium, zirconium, titanium, and oxygen), gadolinium ferrate (GdFeO₃, which is a material comprising gadolinium, iron, and oxygen), gadolinium lanthanum iron oxide (Ga,La)FeO₃ (which is a material comprising gadolinium, lanthanum, iron, and oxygen), barium calcium titanium oxide (Ba,Ca)TiO₃ (which is a material comprising barium, calcium, titanium, and oxygen), and barium zirconium titanium oxide Ba(Zr,Ti)O₃ (which is a material comprising barium, zirconium, titanium, and oxygen).

In some embodiments, the soft and hard ferroelectric layers 508 and 512 can comprise perovskites, such as any of the perovskites listed above. In some embodiments, the soft and hard ferroelectric layers 508 and 512 and the top and bottom electrodes 516 and 520 are perovskites.

In some embodiments, the top and bottom electrodes 516 and 520 can comprise a metal, alloy, or other suitable conductor, such as copper, aluminum, cobalt, tungsten, tantalum, nickel, molybdenum, titanium, nickel, or graphene.

While FIG. 5 illustrates an embodiment in which a multi-layer ferroelectric structure comprises two ferroelectric layers, in other embodiments, a multi-layer ferroelectric structure having a low coercive voltage can comprise more than two ferroelectric layers.

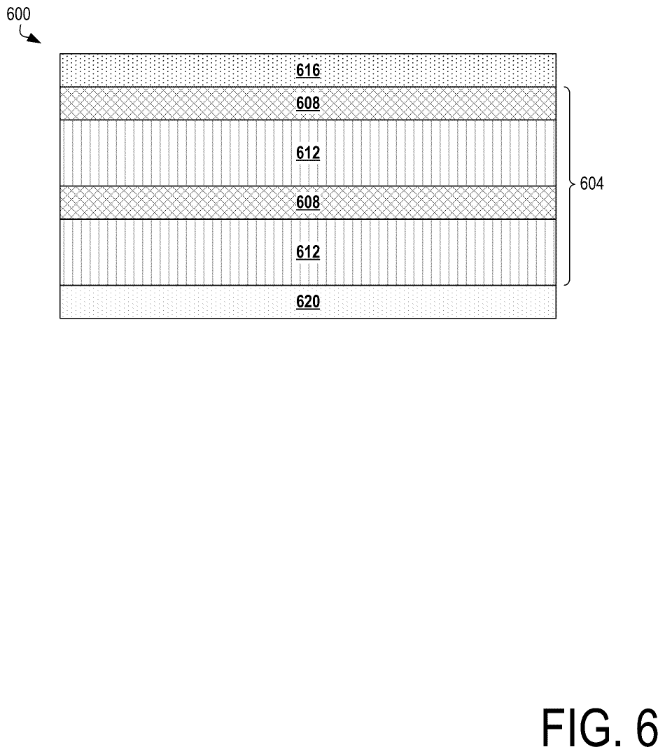

FIG. 6 illustrates a second example capacitor comprising a multi-layer ferroelectric structure. The structure 600 comprises a ferroelectric stack 604 comprising a pair of soft ferroelectric layers 608 interleaved with a pair of hard ferroelectric layers 612. The ferroelectric stack 604 is positioned between a top electrode 616 and a bottom electrode 620. The ferroelectric layers 608 and 612 can comprise any of the ferroelectric layers described herein and the top and bottom electrodes can comprise any electrode or any other layer that can be located on or positioned next to as described herein. While FIG. 6 illustrates two soft ferroelectric layers 608 and two hard ferroelectric layers 612, in other embodiments, the ferroelectric stack 604 can comprise any number of interleaving soft and hard ferroelectric layers. Further, in some embodiments, a ferroelectric stack can comprise an uneven number of layers with the top and bottom ferroelectric layers in the ferroelectric stack 604 being both soft ferroelectric layers or hard ferroelectric layers.

While the multi-layer ferroelectric structures 504 and 604 are illustrated as being part of capacitors, multi-layer ferroelectric structures can be utilized in other types of devices, such as FeFETs.

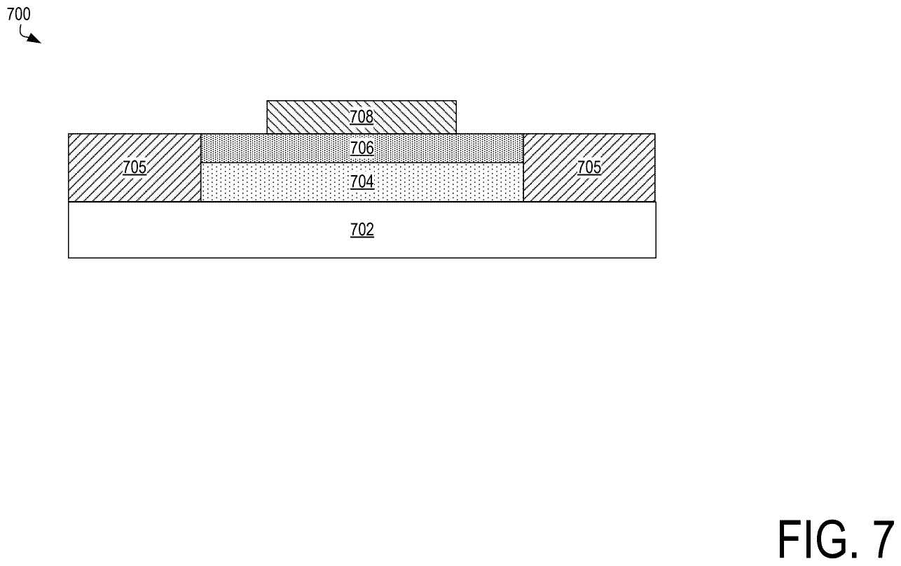

FIG. 7 illustrates an example ferroelectric field effect transistor (FeFET) that can comprise multi-layer magnetoelectric structures. FIG. 7 illustrates an example FeFET device 700. The example device 700 includes a substrate 702 with a semiconductor channel layer 704 formed on the substrate 702 and source/drain regions 705 adjacent to either side of the semiconductor layer 704. The device 700 also includes a multi-layer ferroelectric structure 706 on the semiconductor layer 704 and the source/drain regions 705, and a gate contact 708 on the ferroelectric structure 706.

In operation, when a sufficiently large voltage is applied to the gate contact 708, the polarization direction in the ferroelectric structure 706 may be switched. This induces a change in the charge in the channel within the semiconductor channel layer 704 and modulates the source-drain current of the device 700. Thus, the FeFET can be tuned “on” or “off” through switching of the electrical polarization of the ferroelectric structure.

The semiconductor channel layer 704 can comprise doped barium stannate (BaSnO₃ doped with lanthanum (La), neodymium (Nd), or other dopants), doped strontium titanate (SrTiO₃ doped with lanthanum (La), neodymium (Nd), or other dopants), indium gallium zinc oxide (InGaZnO₄, also known as IGZO, which is a material comprising indium, gallium, zinc, and oxygen), lanthanum niobate (LaNbO₃, which is a material comprising lanthanum, niobium, and oxygen), strontium stannate (SrSnO₃, which is a material comprising strontium, tin, and oxygen), barium strontium stannate ((Ba,Sr)SnO₃, which is a material comprising barium, strontium, and oxygen), or another suitable material.

The gate contact 708 and source/drain regions 705 can comprise SRO, strontium ruthenate (SrRuO₃, which is a material comprising strontium, ruthenium, and oxygen), strontium barium ruthenate ((Sr,Ba)RuO₃, which is a material comprising strontium, barium, ruthenium, and oxygen), lanthanum barium stannate ((La,Ba)SnO₃, which is a material comprising lanthanum, barium, tin, and oxygen), lanthanum strontium manganate ((La,Sr)MnO₃, which is a material comprises lanthanum, manganese, and oxygen), lanthanum barium cobaltate ((La,Ba)CoO₃, which is a material comprising lanthanum, barium, cobalt, and oxygen), lithium niobate (LiNbO₃), lanthanum barium stannate ((La,Ba)SnO₃, which is a material comprising lanthanum, barium, tin, and oxygen), lanthanum ruthenate (LaRuO₃, which is a material comprise lanthanum, ruthenium, and oxygen), yttrium barium copper oxide (YBa₂Cu₃O₇, also known as YBCO, which is a material comprising yttrium, barium, copper, and oxygen), strontium vanadate (SrVO₃, which is a material comprising strontium, vanadium and oxygen), strontium cobaltate (SrCoO₃, which is a material comprising strontium, cobalt, and oxygen), strontium molybdate (SrMoO₃, which is a material comprising strontium, molybdenum, and oxygen), platinum, ruthenium, iridium, palladium, tungsten, molybdenum, ruthenium dioxide (RuO₂), iridium oxide (IrOₓ), and molybdenum(IV) oxide (MoO₂).

The ferroelectric structure 706, which is positioned between the gate contact 708 and the semiconductor channel layer 704, can comprise any of the multi-layer ferroelectric stacks described herein.

The substrate 702 may include an oxide template material, which may be lattice-matched to one or more of the materials grown thereon. For example, the substrate 702 may include an oxide material layer such as strontium titanate (SrTiO₃) which may be on silicon dioxide (SiO₂) layer or similar type of substrate material. Other embodiments may utilize a substrate 702 that includes DyScO₃ or GdScO₃.

Thus, FIG. 7 illustrates that the ferroelectric stacks disclosed herein can be positioned between types of layers or materials other than capacitor electrodes (as illustrated in FIGS. 5 and 6). FIG. 7 illustrates that a ferroelectric structure (706) can be positioned between a gate contact (708) and a semiconductor channel layer (704).

As discussed above, multi-layer ferromagnetic structure can be used in “beyond CMOS” devices, such MESO devices and MEMTJs, as well as magnetoresistive random-access memories (MRAMs) bit cells (such as spin-orbit torque MTJs (SOT-MTJs), and spin-orbit torque MTJs (STT MTJs)). These ferromagnetic structures comprises a soft ferromagnetic layer and a hard ferromagnetic layer, with the soft ferromagnetic layer having a coercive voltage that is lower than the coercive voltage of the hard ferromagnetic layer.

The coercive voltage of the soft and hard ferromagnetic layers and can based on various factors, such as layer thickness, the material that makes up the layer, the processing conditions under which the ferromagnetic layer was formed, and operating temperature. In some embodiments, the thickness of the ferromagnetic layer stack can be less than or about 10 nanometers or another value.

The soft and hard ferromagnetic layers can comprise the same or different materials. In some embodiments, the soft and hard ferromagnetic layers can comprise the same materials, but with a dopant present in one of the layers. In some embodiments, the soft and hard ferromagnetic layers can comprise the same materials but have different dopant concentrations. For example, the concentration of a dopant in one of the ferromagnetic layers can be in a first concentration range and the concentration of the dopant in the other of the ferromagnetic layers can be in a second concentration range. In some embodiments, the first and second concentration ranges can be substantially non-overlapping and in other embodiments, a maximum concentration of the first concentration range can be less than the minimum concentration of the second concentration range.

The soft and hard ferromagnetic layers can comprise any suitable ferromagnetic material, such as cobalt iron (CoFe), CoFeB, and nickel iron (NiFe), CaTiO₃, LSFMO, LSMO, SCRO, SFMO, or magnetite. In some embodiments, the soft and hard ferromagnetic layers can comprise perovskites, such as any ferromagnetic perovskite. In some embodiments, a multi-layer ferromagnetic structure having a low coercive voltage can comprise more than two ferromagnetic layers.

The ferromagnets 310a and 310b of the MESO device 300 illustrated in FIG. 3 and the ferromagnets 424, 428, 436, and 440 can be any of the ferromagnetic structures described herein.

The ferromagnetic structures disclosed herein can be positioned between a variety of materials or layers. For example, with reference to FIG. 4, a first portion of the ferromagnet 310a is positioned between conductive trace 302b and magnetoelectric structure 322 and a second portion of the ferromagnet 310a is positioned between the inter-magnet insulating layer 312 and the magnetoelectric structure 322; and a portion of the ferromagnet 310b is positioned between conductive trace 306 and tunneling barrier 332. With reference to FIG. 4, a first portion of ferromagnet 424 is positioned between electrode 464 and magnetoelectric structure 420 and a second portion of ferromagnet 424 is positioned between insulating layer 412 and magnetoelectric structure 420; a portion of ferromagnet 428 is positioned between insulating layer 412 and ferromagnet 436 or 440; and ferromagnets 436 and 440 are positioned between ferromagnet 428 and electrodes 444 and 448, respectively.

Any of the multi-layer magnetoelectric, ferroelectric, and ferromagnetic structures described herein can be located on or above a substrate. In some embodiments, the substrate comprises silicon or silicon dioxide (SiO₂).

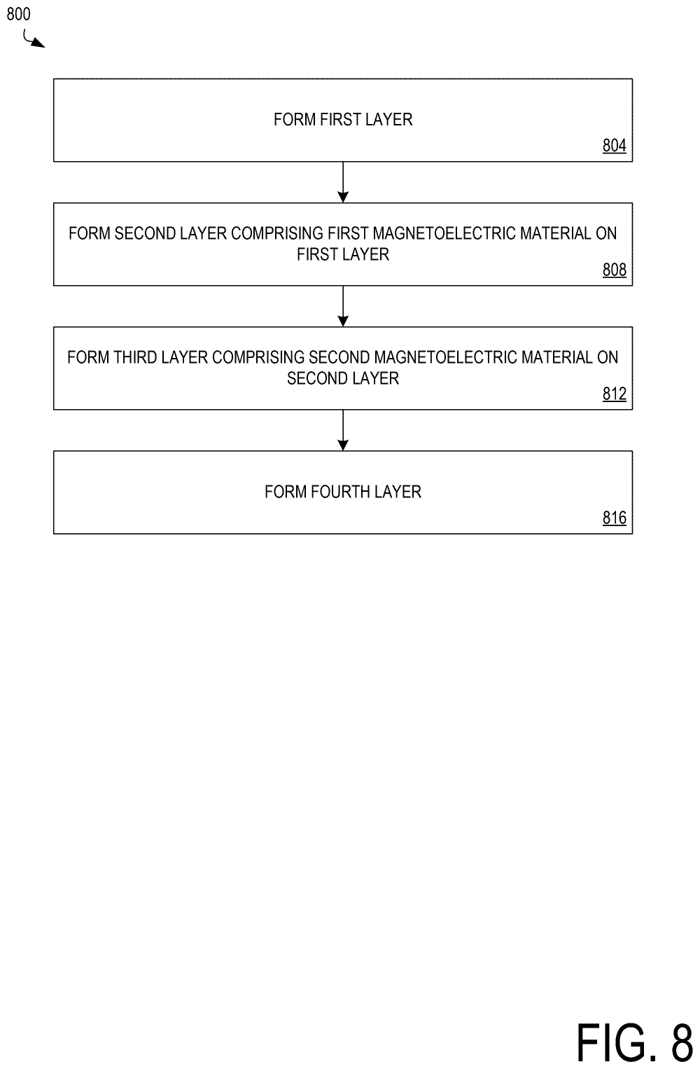

FIG. 8 illustrates an example method for fabricating a multi-layer magnetoelectric structure. The method 800 could be performed by an integrated circuit component manufacturer. The method 800 is only one example methodology for arriving at the magnetoelectric structure described herein. The methods 800 and 900 may be performed using any suitable microelectronic fabrication technique. For example, film deposition—such as depositing layers, filling portions of layers (e.g., removed portions), and filling via openings—may be performed using any suitable deposition techniques, including, for example, chemical vapor deposition (CVD), metalorganic chemical vapor deposition (MOCVD), molecular beam epitaxy (MBE), atomic layer deposition (ALD), sputtering and/or physical vapor deposition (PVD). Moreover, patterning and removal—such as interconnect patterning, forming via openings, and shaping—may be performed using any suitable techniques, such as lithography-based patterning/masking and/or etching. Perovskite materials may be etched, for example, via dry etch (e.g., argon ion etching) or wet etch (e.g., HF wet etch) processes.

At 804 in the method 800, a first layer comprising a first material is formed. At 808, a second layer is formed on the first layer, the second layer comprising a first magnetoelectric material. At 812, a third layer is formed on the second layer, the third layer comprising a second magnetoelectric material. At 816, a fourth layer is formed on the third layer, the fourth layer comprising a second material, the third layer positioned between the second layer and the fourth layer. In other embodiments, the method 800 can comprise one or more additional elements or other limitations. For example, method 800 can further comprise, after forming the third layer, forming a fifth layer on the third layer, the fifth layer comprising the first magnetoelectric material; and after forming the fifth layer, forming a sixth layer on the fifth layer, the sixth layer comprising the second magnetoelectric material, the fifth layer and the sixth layer positioned between the third magnetoelectric layer and the fourth layer.

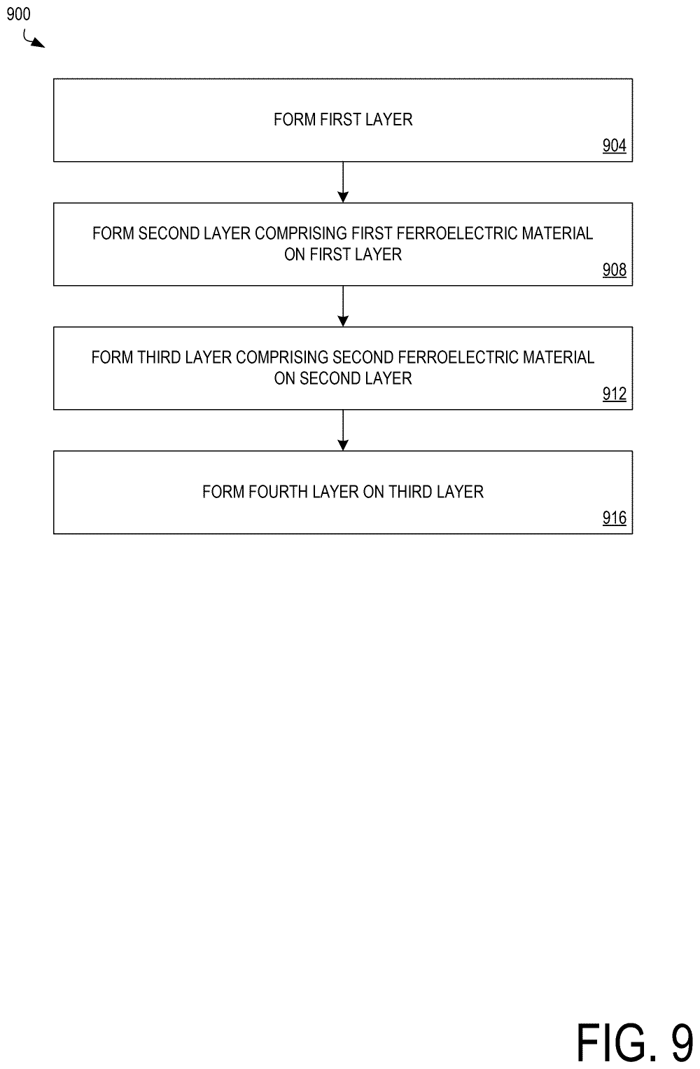

FIG. 9 illustrates an example method for fabricating a multi-layer ferroelectric structure. The method 900 could be performed by an integrated circuit component manufacturer comprises. The method 900 may be performed using any suitable microelectronics fabrication techniques, including those described above as being suitable for performing the method 900. At 904 in the method 900, a first layer comprising a first material is formed. At 908, a second layer is formed on the first layer, the second layer comprising a first ferroelectric material. At 912, a third layer is formed on the second layer, the third layer comprising a second ferroelectric material. At 916, a fourth layer is formed on the third layer, the fourth layer comprising a second material, the third layer positioned between the second layer and the fourth layer. In other embodiments, the method 900 can comprise one or more additional elements or other limitations. For example, method 900 can further comprise, after forming the third layer, forming a fifth layer on the third layer, the fifth layer comprising the first ferroelectric material; and after forming the fifth layer, forming a sixth layer on the fifth layer, the sixth layer comprising the second ferroelectric material, the fifth layer and the sixth layer positioned between the third ferroelectric layer and the fourth layer.

The MESO, MEMTJ, and FeFET devices disclosed herein that can comprise multi-layer magnetoelectric, ferroelectric, or ferromagnetic structures are examples of spintronic devices, devices that utilize a physical variable of magnetization or spin as a computational variable. The multi-layer magnetoelectric, ferroelectric, and ferromagnetic structures can be used in other spintronic devices.

The multi-layer magnetoelectric, ferroelectric, and ferromagnetic structures described herein can be used in any processor unit or integrated circuit component described or referenced herein is an integrated circuit component comprising multi-layer magnetoelectric, ferroelectric, or ferromagnetic structures can be attached to a printed circuit board. In some embodiments, one or more additional integrated circuit components or other components, such as a battery or antenna, can be attached to the printed circuit board. In some embodiments, the printed circuit board and the integrated circuit component can be located in a computing device that comprises a housing that encloses the printed circuit board and the integrated circuit component is an integrated circuit structure comprising devices that include magnetoelectric, ferroelectric, or ferromagnetic structures can comprise other types of devices, such as electronic transistors (transistors such as CMOS transistors that operate through control of the flow of electric current and that do not rely upon the switching of the magnetization of a layer or component for operation).

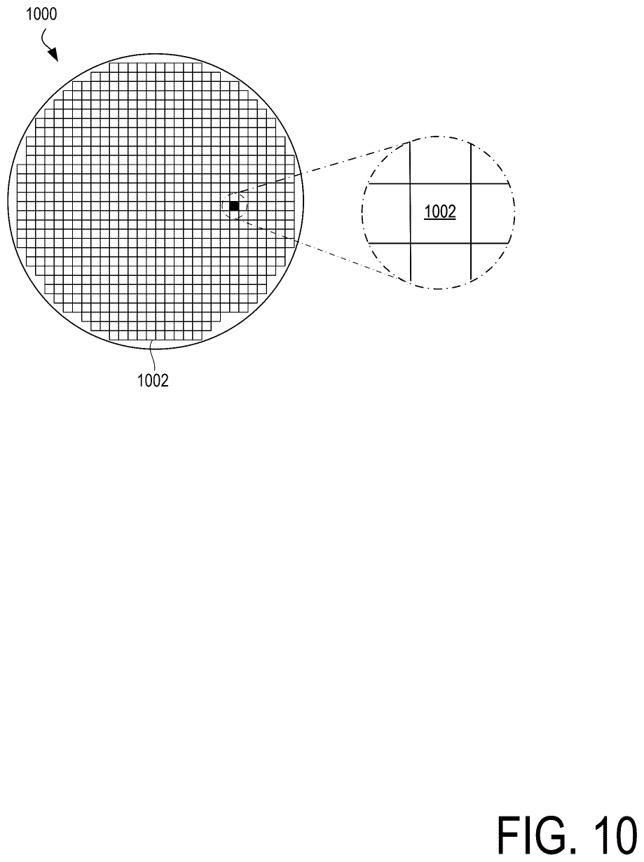

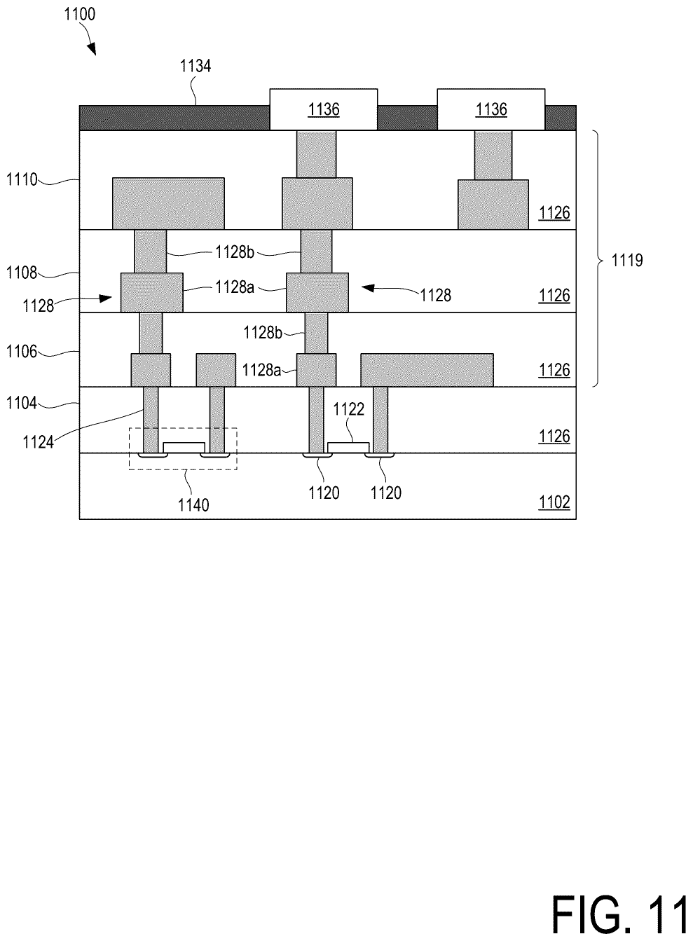

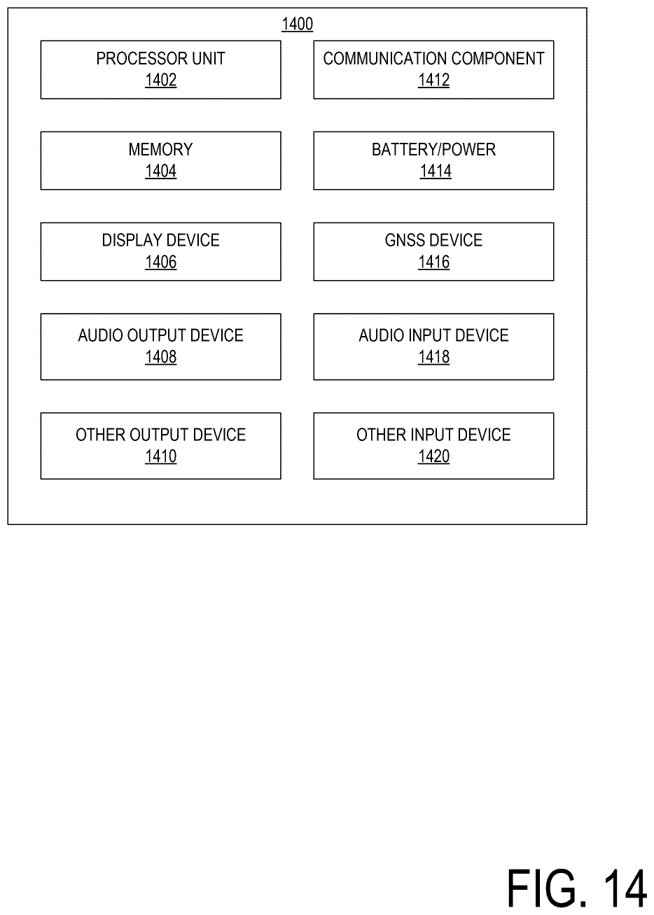

FIG. 10 is a top view of a wafer 1000 and dies 1002 that may include one or more multi-layer magnetoelectric, ferroelectric, or ferromagnetic structures as disclosed herein. The wafer 1000 may be composed of semiconductor material and may include one or more dies 1002 having integrated circuit structures formed on a surface of the wafer 1000. The individual dies 1002 may be a repeating unit of an integrated circuit product that includes any suitable integrated circuit. After the fabrication of the integrated circuit product is complete, the wafer 1000 may undergo a singulation process in which the dies 1002 are separated from one another to provide discrete “chips” of the integrated circuit product. The die 1002 may be any of the processing units or integrated circuit components disclosed herein. The die 1002 may include one or more transistors (e.g., some of the electronic transistors 1140 of FIG. 11, discussed below, spintronic transistors, supporting circuitry to route electrical signals to the transistors, passive components (e.g., signal traces, resistors, capacitors, or inductors), and/or any other integrated circuit components. In some embodiments, the wafer 1000 or the die 1002 may include a memory device, a logic device (e.g., an AND, OR, NAND, or NOR gate), or any other suitable circuit element. Multiple ones of these devices may be combined on a single die 1002. For example, a memory array formed by multiple memory devices may be formed on a same die 1002 as a processor unit (e.g., the processor unit 1402 of FIG. 14) or other logic that is configured to store information in the memory devices or execute instructions stored in the memory array. Various microelectronic assemblies may be manufactured using a die-to-wafer assembly technique in which some dies are attached to a wafer 1000 that includes others of the dies, and the wafer 1000 is subsequently singulated.

FIG. 11 is a cross-sectional side view of an integrated circuit device 1100 that may be included in any of the processor units, integrated circuit components or other components disclosed or referenced herein. One or more of the integrated circuit devices 1100 may be included in one or more dies 1002 (FIG. 10). The integrated circuit device 1100 may be formed on a die substrate 1102 (e.g., the wafer 1000 of FIG. 10) and may be included in a die (e.g., the die 1002 of FIG. 10). The die substrate 1102 may be a semiconductor substrate composed of semiconductor material systems including, for example, n-type or p-type materials systems (or a combination of both). The die substrate 1102 may include, for example, a crystalline substrate formed using a bulk silicon or a silicon-on-insulator (SOI) substructure. In some embodiments, the die substrate 1102 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1102. Although a few examples of materials from which the die substrate 1102 may be formed are described here, any material that may serve as a foundation for an integrated circuit device 1100 may be used. The die substrate 1102 may be part of a singulated die (e.g., the dies 1002 of FIG. 10) or a wafer (e.g., the wafer 1000 of FIG. 10).

The integrated circuit device 1100 may include one or more device layers 1104 disposed on the die substrate 1102. The device layer 1104 may include features of one or more electronic transistors 1140 (e.g., metal oxide semiconductor field-effect transistors (MOSFETs)) formed on the die substrate 1102. The transistors 1140 may include, for example, one or more source and/or drain (S/D) regions 1120, a gate 1122 to control current flow between the S/D regions 1120, and one or more S/D contacts 1124 to route electrical signals to/from the S/D regions 1120. The transistors 1140 may include additional features not depicted for the sake of clarity, such as device isolation regions, gate contacts, and the like. The transistors 1140 are not limited to the type and configuration depicted in FIG. 11 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors. The integrated circuit device 1100 can further include spintronic devices, such as the MESO devices described herein.

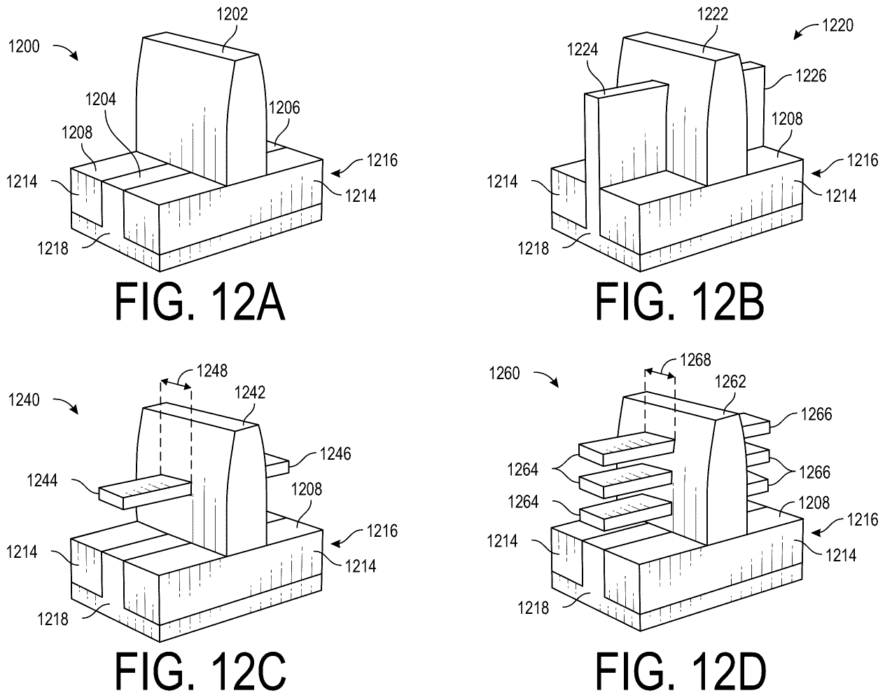

FIGS. 12A-15D are simplified perspective views of example planar, FinFET, gate-all-around, and stacked gate-all-around field-effect transistors. The transistors illustrated in FIGS. 12A-15D are formed on a substrate 1216 having a surface 1208. Isolation regions 1214 separate the source and drain regions of the transistors from other transistors and from a bulk region 1218 of the substrate 1216.

FIG. 12A is a perspective view of an example planar transistor 1200 comprising a gate 1202 that controls current flow between a source region 1204 and a drain region 1206. The transistor 1200 is planar in that the source region 1204 and the drain region 1206 are planar with respect to the substrate surface 1208.

FIG. 12B is a perspective view of an example FinFET transistor 1220 comprising a gate 1222 that controls current flow between a source region 1224 and a drain region 1226. The transistor 1220 is non-planar in that the source region 1224 and the drain region 1226 comprise “fins” that extend upwards from the substrate surface 1208. As the gate 1222 encompasses three sides of the semiconductor fin that extends from the source region 1224 to the drain region 1226, the transistor 1220 can be considered a tri-gate transistor. FIG. 12B illustrates only one S/D fin extending through the gate 1222, but multiple S/D fins can extend through the gate of a FinFET transistor.

FIG. 12C is a perspective view of a gate-all-around (GAA) transistor 1240 comprising a gate 1242 that controls current flow between a source region 1244 and a drain region 1246. The transistor 1240 is non-planar in that the source region 1244 and the drain region 1246 are elevated from the substrate surface 1208.

FIG. 12D is a perspective view of a GAA transistor 1260 comprising a gate 1262 that controls current flow between multiple elevated source regions 1264 and multiple elevated drain regions 1266. The transistor 1260 is a stacked GAA transistor as the gate controls the flow of current between multiple elevated S/D regions stacked on top of each other. The transistors 1240 and 1260 are considered gate-all-around transistors as the gates encompass all sides of the semiconductor portions that extend from the source regions to the drain regions. The transistors 1240 and 1260 can alternatively be referred to as nanowire, nanosheet, or nanoribbon transistors depending on the width (e.g., widths 1248 and 1268 of transistors 1240 and 1260, respectively) of the semiconductor portions extending through the gate.

Returning to FIG. 11, a transistor 1140 may include a gate 1122 formed of at least two layers, a gate dielectric, and a gate electrode (or conductive trace). The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1140 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1140 along the source-channel-drain direction, the gate electrode may consist of a U-shaped structure that includes a bottom portion substantially parallel to the surface of the die substrate 1102 and two sidewall portions that are substantially perpendicular to the top surface of the die substrate 1102. In other embodiments, at least one of the metal layers that form the gate electrode may simply be a planar layer that is substantially parallel to the top surface of the die substrate 1102 and does not include sidewall portions substantially perpendicular to the top surface of the die substrate 1102. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1120 may be formed within the die substrate 1102 adjacent to the gate 1122 of individual transistors 1140. The S/D regions 1120 may be formed using an implantation/diffusion process or an etching/deposition process, for example. In the former process, dopants such as boron, aluminum, antimony, phosphorous, or arsenic may be ion-implanted into the die substrate 1102 to form the S/D regions 1120. An annealing process that activates the dopants and causes them to diffuse farther into the die substrate 1102 may follow the ion-implantation process. In the latter process, the die substrate 1102 may first be etched to form recesses at the locations of the S/D regions 1120. An epitaxial deposition process may then be carried out to fill the recesses with material that is used to fabricate the S/D regions 1120. In some implementations, the S/D regions 1120 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1120 may be formed using one or more alternate semiconductor materials such as germanium or a group III-V material or alloy. In further embodiments, one or more layers of metal and/or metal alloys may be used to form the S/D regions 1120.

Electrical signals, such as power and/or input/output (I/O) signals, may be routed to and/or from the devices (e.g., transistors 1140) of the device layer 1104 through one or more interconnect layers disposed on the device layer 1104 (illustrated in FIG. 11 as interconnect layers 1106-1110). For example, electrically conductive features of the device layer 1104 (e.g., the gate 1122 and the S/D contacts 1124) may be electrically coupled with the interconnect structures 1128 of the interconnect layers 1106-1110. The one or more interconnect layers 1106-1110 may form a metallization stack (also referred to as an “ILD stack”) 1119 of the integrated circuit device 1100.

The interconnect structures 1128 may be arranged within the interconnect layers 1106-1110 to route electrical signals according to a wide variety of designs; in particular, the arrangement is not limited to the particular configuration of interconnect structures 1128 depicted in FIG. 11. Although a particular number of interconnect layers 1106-1110 is depicted in FIG. 11, embodiments of the present disclosure include integrated circuit devices having more or fewer interconnect layers than depicted.

In some embodiments, the interconnect structures 1128 may include lines 1128a and/or vias 1128b filled with an electrically conductive material such as a metal. The lines 1128a may be arranged to route electrical signals in a direction of a plane that is substantially parallel with a surface of the die substrate 1102 upon which the device layer 1104 is formed. For example, the lines 1128a may route electrical signals in a direction in and out of the page and/or in a direction across the page from the perspective of FIG. 4. The vias 1128b may be arranged to route electrical signals in a direction of a plane that is substantially perpendicular to the surface of the die substrate 1102 upon which the device layer 1104 is formed. In some embodiments, the vias 1128b may electrically couple lines 1128a of different interconnect layers 1106-1110 together.

The interconnect layers 1106-1110 may include a dielectric material 1126 disposed between the interconnect structures 1128, as shown in FIG. 11. The dielectric material 1126 disposed between the interconnect structures can be referred to as an inter-layer dielectric (ILD). In some embodiments, dielectric material 1126 disposed between the interconnect structures 1128 in different ones of the interconnect layers 1106-1110 may have different compositions; in other embodiments, the composition of the dielectric material 1126 between different interconnect layers 1106-1110 may be the same. In some embodiments, dielectric 1126 the interconnect structures 1128 can comprise a perovskite material. The device layer 1104 may include a dielectric material 1126 disposed between the transistors 1140 and a bottom layer of the metallization stack as well. The dielectric material 1126 included in the device layer 1104 may have a different composition than the dielectric material 1126 included in the interconnect layers 1106-1110; in other embodiments, the composition of the dielectric material 1126 in the device layer 1104 may be the same as a dielectric material 1126 included in any one of the interconnect layers 1106-1110. The one or more interconnect layers 1106-1110 plus the dielectric layers between the interconnect layers 706-710 may form a metallization stack (also referred to as an “ILD stack” (inter-layer dielectric stack)) 1119 of the integrated circuit device 1100.

A first interconnect layer 1106 (referred to as Metal 1 or “M1”) may be formed directly on the device layer 1104. In some embodiments, the first interconnect layer 1106 may include lines 1128a and/or vias 1128b, as shown. The lines 1128a of the first interconnect layer 1106 may be coupled with contacts (e.g., the S/D contacts 1124) of the device layer 1104. The vias 1128b of the first interconnect layer 1106 may be coupled with the lines 1128a of a second interconnect layer 1108.

The second interconnect layer 1108 (referred to as Metal 2 or “M2”) may be formed directly on the first interconnect layer 1106. In some embodiments, the second interconnect layer 1108 may include via 1128b to couple the lines 1128 of the second interconnect layer 1108 with the lines 1128a of a third interconnect layer 1110. Although the lines 1128a and the vias 1128b are structurally delineated with a line within individual interconnect layers for the sake of clarity, the lines 1128a and the vias 1128b may be structurally and/or materially contiguous (e.g., simultaneously filled during a dual-damascene process) in some embodiments.

The third interconnect layer 1110 (referred to as Metal 3 or “M3”)(and additional interconnect layers, as desired) may be formed in succession on the second interconnect layer 1108 according to similar techniques and configurations described in connection with the second interconnect layer 1108 or the first interconnect layer 1106. In some embodiments, the interconnect layers that are “higher up” in the metallization stack 1119 in the integrated circuit device 1100 (i.e., farther away from the device layer 1104) may be thicker that the interconnect layers that are lower in the metallization stack 1119, with lines 1128a and vias 1128b in the higher interconnect layers being thicker than those in the lower interconnect layers.

In some embodiments, MESO devices can be fabricated within the ILD stack. That is, a MESO device can be fabricated between adjacent interconnect layers (e.g., between Metal 2 and Metal 3 layers) or non-adjacent interconnect layers. A via can be used to connect a MESO device electrode to an interconnect. In some embodiments, a MESO device electrode can connect to an interconnect layer by being positioned adjacent to an interconnect layer.

The integrated circuit device 1100 may include a solder resist material 1134 (e.g., polyimide or similar material) and one or more conductive contacts 1136 formed on the interconnect layers 1106-1110. In FIG. 11, the conductive contacts 1136 are illustrated as taking the form of bond pads. The conductive contacts 1136 may be electrically coupled with the interconnect structures 1128 and configured to route the electrical signals of the transistor(s) 1140 to external devices. For example, solder bonds may be formed on the one or more conductive contacts 1136 to mechanically and/or electrically couple an integrated circuit die including the integrated circuit device 1100 with another component (e.g., a printed circuit board). The integrated circuit device 1100 may include additional or alternate structures to route the electrical signals from the interconnect layers 1106-1110; for example, the conductive contacts 1136 may include other analogous features (e.g., posts) that route the electrical signals to external components.

In some embodiments in which the integrated circuit device 1100 is a double-sided die, the integrated circuit device 1100 may include another metallization stack (not shown) on the opposite side of the device layer(s) 1104. This metallization stack may include multiple interconnect layers as discussed above with reference to the interconnect layers 1106-1110, to provide conductive pathways (e.g., including conductive lines and vias) between the device layer(s) 1104 and additional conductive contacts (not shown) on the opposite side of the integrated circuit device 1100 from the conductive contacts 1136.

In other embodiments in which the integrated circuit device 1100 is a double-sided die, the integrated circuit device 1100 may include one or more through silicon vias (TSVs) through the die substrate 1102; these TSVs may make contact with the device layer(s) 1104, and may provide conductive pathways between the device layer(s) 1104 and additional conductive contacts (not shown) on the opposite side of the integrated circuit device 1100 from the conductive contacts 1136. In some embodiments, TSVs extending through the substrate can be used for routing power and ground signals from conductive contacts on the opposite side of the integrated circuit device 1100 from the conductive contacts 1136 to the transistors 1140 and any other components integrated into the die 1100, and the metallization stack 1119 can be used to route I/O signals from the conductive contacts 1136 to transistors 1140 and any other components integrated into the die 1100.

Multiple integrated circuit devices 1100 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

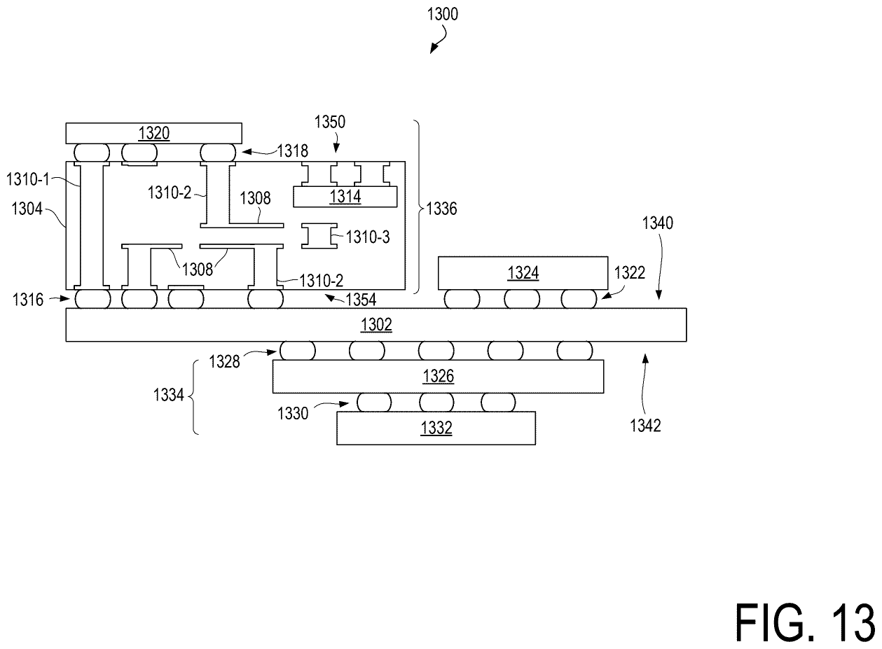

FIG. 13 is a cross-sectional side view of an integrated circuit device assembly 1300 that may include a processor unit, integrated circuit component, or other components comprising magnetoelectric, ferroelectric, or ferromagnetic structures. The integrated circuit device assembly 1300 includes a number of components disposed on a circuit board 1302 (which may be a motherboard, system board, mainboard, etc.). The integrated circuit device assembly 1300 includes components disposed on a first face 1340 of the circuit board 1302 and an opposing second face 1342 of the circuit board 1302; generally, components may be disposed on one or both faces 1340 and 1342.

In some embodiments, the circuit board 1302 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1302. In other embodiments, the circuit board 1302 may be a non-PCB substrate. The integrated circuit device assembly 1300 illustrated in FIG. 13 includes a package-on-interposer structure 1336 coupled to the first face 1340 of the circuit board 1302 by coupling components 1316. The coupling components 1316 may electrically and mechanically couple the package-on-interposer structure 1336 to the circuit board 1302, and may include solder balls (as shown in FIG. 13), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1336 may include an integrated circuit component 1320 coupled to an interposer 1304 by coupling components 1318. The coupling components 1318 may take any suitable form for the application, such as the forms discussed above with reference to the coupling components 1316. Although a single integrated circuit component 1320 is shown in FIG. 13, multiple integrated circuit components may be coupled to the interposer 1304; indeed, additional interposers may be coupled to the interposer 1304. The interposer 1304 may provide an intervening substrate used to bridge the circuit board 1302 and the integrated circuit component 1320.

The integrated circuit component 1320 may be a packaged or unpacked integrated circuit product that includes one or more integrated circuit dies (e.g., the die 1002 of FIG. 10, the integrated circuit device 1100 of FIG. 11) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1320, a single monolithic integrated circuit die comprises solder bumps attached to contacts on the die. The solder bumps allow the die to be directly attached to the interposer 1304. The integrated circuit component 1320 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1320 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1320 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1320 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1304 may spread connections to a wider pitch or reroute a connection to a different connection. For example, the interposer 1304 may couple the integrated circuit component 1320 to a set of ball grid array (BGA) conductive contacts of the coupling components 1316 for coupling to the circuit board 1302. In the embodiment illustrated in FIG. 13, the integrated circuit component 1320 and the circuit board 1302 are attached to opposing sides of the interposer 1304; in other embodiments, the integrated circuit component 1320 and the circuit board 1302 may be attached to a same side of the interposer 1304. In some embodiments, three or more components may be interconnected by way of the interposer 1304.

In some embodiments, the interposer 1304 may be formed as a PCB, including multiple metal layers separated from one another by layers of dielectric material and interconnected by electrically conductive vias. In some embodiments, the interposer 1304 may be formed of an epoxy resin, a fiberglass-reinforced epoxy resin, an epoxy resin with inorganic fillers, a ceramic material, or a polymer material such as polyimide. In some embodiments, the interposer 1304 may be formed of alternate rigid or flexible materials that may include the same materials described above for use in a semiconductor substrate, such as silicon, germanium, and other group III-V and group IV materials. The interposer 1304 may include metal interconnects 1308 and vias 1310, including but not limited to through hole vias 1310-1 (that extend from a first face 1350 of the interposer 1304 to a second face 1354 of the interposer 1304), blind vias 1310-2 (that extend from the first or second faces 1350 or 1354 of the interposer 1304 to an internal metal layer), and buried vias 1310-3 (that connect internal metal layers).

In some embodiments, the interposer 1304 can comprise a silicon interposer. Through silicon vias (TSV) extending through the silicon interposer can connect connections on a first face of a silicon interposer to an opposing second face of the silicon interposer. In some embodiments, an interposer 1304 comprising a silicon interposer can further comprise one or more routing layers to route connections on a first face of the interposer 1304 to an opposing second face of the interposer 1304.

The interposer 1304 may further include embedded devices 1314, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1304. The package-on-interposer structure 1336 may take the form of any of the package-on-interposer structures known in the art. In embodiments where the interposer is a non-printed circuit board

The integrated circuit device assembly 1300 may include an integrated circuit component 1324 coupled to the first face 1340 of the circuit board 1302 by coupling components 1322. The coupling components 1322 may take the form of any of the embodiments discussed above with reference to the coupling components 1316, and the integrated circuit component 1324 may take the form of any of the embodiments discussed above with reference to the integrated circuit component 1320.

The integrated circuit device assembly 1300 illustrated in FIG. 13 includes a package-on-package structure 1334 coupled to the second face 1342 of the circuit board 1302 by coupling components 1328. The package-on-package structure 1334 may include an integrated circuit component 1326 and an integrated circuit component 1332 coupled together by coupling components 1330 such that the integrated circuit component 1326 is disposed between the circuit board 1302 and the integrated circuit component 1332. The coupling components 1328 and 1330 may take the form of any of the embodiments of the coupling components 1316 discussed above, and the integrated circuit components 1326 and 1332 may take the form of any of the embodiments of the integrated circuit component 1320 discussed above. The package-on-package structure 1334 may be configured in accordance with any of the package-on-package structures known in the art.

FIG. 14 is a block diagram of an example electrical device 1400 that may include one or more of integrated circuit components comprising the magnetoelectric, ferroelectric, or ferromagnetic structures disclosed herein. Any suitable ones of the components of the electrical device 1400 may include one or more of the integrated circuit device assemblies 1300, integrated circuit components 1320, integrated circuit devices 1100, or integrated circuit dies 1002 disclosed herein. A number of components are illustrated in FIG. 14 as included in the electrical device 1400, but any one or more of these components may be omitted or duplicated, as suitable for the application. In some embodiments, some or all of the components included in the electrical device 1400 may be attached to one or more motherboards, mainboards, system boards, or other printed circuit boards. In some embodiments, one or more of these components are fabricated onto a single system-on-a-chip (SoC) die.

Additionally, in various embodiments, the electrical device 1400 may not include one or more of the components illustrated in FIG. 14, but the electrical device 1400 may include interface circuitry for coupling to the one or more components. For example, the electrical device 1400 may not include a display device 1406, but may include display device interface circuitry (e.g., a connector and driver circuitry) to which a display device 1406 may be coupled. In another set of examples, the electrical device 1400 may not include an audio input device 1418 or an audio output device 1408, but may include audio input or output device interface circuitry (e.g., connectors and supporting circuitry) to which an audio input device 1418 or audio output device 1408 may be coupled.

The electrical device 1400 may include one or more processor units 1402 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1402 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1400 may include a memory 1404, which may itself include one or more memory devices such as volatile memory (e.g., dynamic random-access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1404 may include memory that is located on the same integrated circuit die as the processor unit 1402. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments, the electrical device 1400 can comprise one or more processor units 1402 that are heterogeneous or asymmetric to another processor unit 1402 in the electrical device 1400. There can be a variety of differences between the processing units 1402 in a system in terms of a spectrum of metrics of merit including architectural, microarchitectural, thermal, power consumption characteristics, and the like. These differences can effectively manifest themselves as asymmetry and heterogeneity among the processor units 1402 in the electrical device 1400.

In some embodiments, the electrical device 1400 may include a communication component 1412 (e.g., one or more communication components). For example, the communication component 1412 can manage wireless communications for the transfer of data to and from the electrical device 1400. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1412 may implement any of a number of wireless standards or protocols. In some embodiments, the communication component 1412 may manage wired communications, such as electrical, optical, or any other suitable communication protocols (e.g., IEEE 802.3 Ethernet standards).

The electrical device 1400 may include battery/power circuitry 1414. The battery/power circuitry 1414 may include one or more energy storage devices (e.g., batteries or capacitors) and/or circuitry for coupling components of the electrical device 1400 to an energy source separate from the electrical device 1400 (e.g., AC line power).

The electrical device 1400 may include a display device 1406 (or corresponding interface circuitry, as discussed above). The display device 1406 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1400 may include an audio output device 1408 (or corresponding interface circuitry, as discussed above). The audio output device 1408 may include any embedded or wired or wirelessly connected external device that generates an audible indicator, such speakers, headsets, or earbuds.

The electrical device 1400 may include another output device 1410 (or corresponding interface circuitry, as discussed above). Examples of the other output device 1410 may include an audio codec, a video codec, a printer, a wired or wireless transmitter for providing information to other devices, or an additional storage device.

The electrical device 1400 may include an audio input device 1418 (or corresponding interface circuitry, as discussed above). The audio input device 1418 may include any embedded or wired or wirelessly connected device that generates a signal representative of a sound, such as microphones, microphone arrays, or digital instruments (e.g., instruments having a musical instrument digital interface (MIDI) output). The electrical device 1400 may include a Global Navigation Satellite System (GNSS) device 1416 (or corresponding interface circuitry, as discussed above), such as a Global Positioning System (GPS) device.

The electrical device 1400 may include another output device 1410 (or corresponding interface circuitry, as discussed above). Examples of the other output device 1410 may include an audio codec, a video codec, a printer, a wired or wireless transmitter for providing information to other devices, or an additional storage device.

The electrical device 1400 may include another input device 1420 (or corresponding interface circuitry, as discussed above). Examples of the other input device 1420 may include an accelerometer, a gyroscope, a compass, an image capture device (e.g., monoscopic or stereoscopic camera), a touchpad, a keyboard, a mouse, a stylus, or a touchscreen.

The electrical device 1400 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1400 may be any other electronic device that processes data. In some embodiments, the electrical device 1400 may comprise multiple discrete physical components. Given the range of devices that the electrical device 1400 can be manifested as in various embodiments, in some embodiments, the electrical device 1400 can be referred to as a computing device or a computing system. Further, the terms “computing device” and “computing system” as used herein are used interchangeably, and the term “apparatus” can refer to an electrical device, a computing device, or a computing system.

As used in this application and the claims, a list of items joined by the term “and/or” can mean any combination of the listed items. For example, the phrase “A, B and/or C” can mean A; B; C; A and B; A and C; B and C; or A, B and C. As used in this application and the claims, a list of items joined by the term “at least one of” can mean any combination of the listed terms. For example, the phrase “at least one of A, B, or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B, and C” can mean A; B; C; A and B; A and C; B and C; or A, B, and C.

As used in this application and the claims, the phrase “individual of” or “respective of” followed by a list of items recited or stated as having a trait, feature, etc. means that all of the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

The following examples pertain to additional embodiments of technologies disclosed herein.

Example 1 is an apparatus comprising: a first layer comprising a first material; a second layer comprising a first magnetoelectric material; a third layer comprising a second magnetoelectric material, the second layer located on the third layer, the second layer located between the first layer and the third layer; and a fourth layer comprising a second material, the third layer located between the second layer and the fourth layer.

Example 2 comprises the apparatus of Example 1, wherein a thickness of the second layer plus the third layer is about 10 nanometers or less.

Example 3 comprises the apparatus of Example 1 or 2, further comprising: a fifth layer comprising the first magnetoelectric material, the third layer located on the fifth layer; and a sixth layer comprising the second magnetoelectric material, the fifth layer located on the sixth layer, the fifth layer located between the third layer and the sixth layer, the sixth layer located between the fifth layer on the fourth layer.

Example 4 comprises the apparatus of any one of Examples 1-3, wherein the first magnetoelectric material and the second magnetoelectric material are the same.

Example 5 comprises the apparatus of any one of Examples 1-3, wherein the first magnetoelectric material and the second magnetoelectric material are perovskites.

Example 6 comprises the apparatus of Example 5, wherein the first material and the second material are perovskites.

Example 7 comprises the apparatus of any one of Examples 1-3, wherein the first magnetoelectric material and the second magnetoelectric material comprise bismuth, iron, and oxygen.

Example 8 comprises the apparatus of Example 7, wherein the first magnetoelectric material and/or the second magnetoelectric material further comprises lanthanum.

Example 9 comprises the apparatus of Example 7, wherein the first magnetoelectric material and/or the second magnetoelectric material further comprises samarium.

Example 10 comprises the apparatus of any one of Examples 1-3, wherein the first magnetoelectric material and the second magnetoelectric material comprise lutetium, iron, and oxygen.

Example 11 comprises the apparatus of any one of Examples 1-3, wherein the first magnetoelectric material and the second magnetoelectric material comprise barium, titanium, and oxygen.

Example 12 comprises the apparatus of any one of Examples 1-3, wherein the first magnetoelectric material and the second magnetoelectric material comprise lead, zirconium, titanium, and oxygen.

Example 13 comprises the apparatus of any one of Examples 1-3, wherein the first magnetoelectric material and the second magnetoelectric material comprise lead, magnesium, niobium, oxygen, and titanium.

Example 14 comprises the apparatus of any one of Examples 1-3, wherein the first magnetoelectric material and the second magnetoelectric material comprise chromium and oxygen.

Example 15 comprises the apparatus of Example 14, wherein the first magnetoelectric material or the second magnetoelectric material further comprises boron.

Example 16 comprises the apparatus of any one of Examples 1-3, wherein the first magnetoelectric material and the second magnetoelectric material comprise terbium, manganese, and oxygen.

Example 17 comprises the apparatus of any one of Examples 1-3, wherein the first magnetoelectric material and the second magnetoelectric material comprise iron and gallium.

Example 18 comprises the apparatus of any one of Examples 1-3, wherein the first magnetoelectric material and the second magnetoelectric material comprise terbium, dysprosium, and iron.

Example 19 comprises the apparatus of any one of Examples 1-3, wherein the first magnetoelectric material and the second magnetoelectric material comprise iron, tellurium, and oxygen.

Example 20 comprises the apparatus of any one of Examples 1-3, wherein the first magnetoelectric material and the second magnetoelectric material comprise iron and rhodium.

Example 21 comprises the apparatus of any one of Examples 1-3, wherein the first magnetoelectric material comprises: bismuth, iron, and oxygen; bismuth, iron, oxygen, and lanthanum; bismuth, iron, oxygen, and samarium; lutetium, iron, and oxygen; terbium, manganese, and oxygen; bismuth, titanium, and oxygen; lead, zirconium, titanium, and oxygen; lead, magnesium, niobium, titanium, and oxygen; chromium, and oxygen; chromium, oxygen, and boron; boron and gallium; terbium, dysprosium, and iron; or iron, tellurium, and oxygen; wherein the second magnetoelectric material comprises: bismuth, iron, and oxygen; bismuth, iron, oxygen, and lanthanum; bismuth, iron, oxygen, and samarium; lutetium, iron, and oxygen; terbium, manganese, and oxygen; bismuth, titanium, and oxygen; lead, magnesium, niobium, titanium, and oxygen; chromium, and oxygen; chromium, and oxygen; chromium, oxygen, and boron; boron and gallium; terbium, dysprosium, and iron; or iron, tellurium, and oxygen.

Example 22 comprises the apparatus of any one of Examples 1-3, wherein the first magnetoelectric material comprises lead, zirconium, titanium, and oxygen; wherein the second magnetoelectric material comprises lead, magnesium, niobium, oxygen, and titanium.

Example 23 comprises the apparatus of any one of Examples 1-3, wherein the first magnetoelectric material comprises: bismuth, iron, and oxygen; bismuth, iron, oxygen, and lanthanum; bismuth, iron, oxygen, and samarium; lutetium, iron, and oxygen; terbium, manganese, and oxygen; bismuth, titanium, and oxygen; lead, magnesium, niobium, titanium, and oxygen; chromium, and oxygen; chromium, and oxygen; or chromium, oxygen, and boron; wherein the second magnetoelectric material comprises: bismuth, iron, and oxygen; bismuth, iron, oxygen, and lanthanum; bismuth, iron, oxygen, and samarium; lutetium, iron, and oxygen; terbium, manganese, and oxygen; bismuth, titanium, and oxygen; lead, magnesium, niobium, titanium, and oxygen; chromium, and oxygen; chromium, and oxygen; or chromium, oxygen, and boron.

Example 24 comprises the apparatus of any one of Examples 1-23, wherein the first magnetoelectric material and the second magnetoelectric material are the same except for the first magnetoelectric material or the second magnetoelectric material further comprising a dopant.

Example 25 comprises the apparatus of any one of Examples 1-23, wherein the first magnetoelectric material comprises a first dopant having a first concentration range in the first magnetoelectric material, the second magnetoelectric material comprises the first dopant having a second concentration range in the second magnetoelectric material, a maximum concentration of the first concentration range is less than a minimum concentration of the second concentration range.

Example 26 comprises the apparatus of any one of Examples 1-23, wherein the first magnetoelectric material comprises a first dopant having a first concentration range in the first magnetoelectric material, the second magnetoelectric material comprises the first dopant having a second concentration range in the second magnetoelectric material, the first concentration range substantially non-overlaps with the second concentration range.

Example 27 comprises the apparatus of any one of Examples 1-26, wherein the first material or the second material comprises: cobalt and iron; cobalt, iron, and boron; nickel and iron; lanthanum, strontium, manganese, and oxygen; lanthanum, strontium, iron, molybdenum, and oxygen; or calcium, titanium, and oxygen.

Example 28 comprises the apparatus of any one of Examples 1-26, wherein the first material or the second material comprises: lanthanum, strontium, manganese, and oxygen; niobium, strontium, titanium, and oxygen; or strontium, ruthenium, and oxygen.

Example 29 comprises the apparatus of any one of Examples 1-26, wherein the first material comprises: cobalt and iron; cobalt, iron, and boron; or nickel and iron.

Example 30 comprises the apparatus of any one of Examples 1-3, wherein the second magnetoelectric material comprises bismuth, iron, and oxygen, and the second material comprises strontium, ruthenium, and oxygen.

Example 31 is an integrated circuit component comprising: a first layer comprising a first material; a second layer comprising a first ferroelectric material; a third layer comprising a second ferroelectric material, the second layer located on the third layer, the second layer located between the first layer and the third layer, wherein the first ferroelectric material is different from the second ferroelectric material; and a fourth layer comprising a second material, the third layer located between the second layer and the fourth layer.

Example 32 comprises the integrated circuit component of Example 31, wherein a thickness of the second layer plus the third layer is about 10 nanometers or less.

Example 33 comprises the integrated circuit component of Example 31 or 32, further comprising: a fifth layer comprising the first ferroelectric material, the third layer located on the fifth layer; and a sixth layer comprising the second ferroelectric material, the fifth layer located on the sixth layer, the fifth layer located between the third layer and the sixth layer, the sixth layer located between the fifth layer on the fourth layer.

Example 34 comprises the integrated circuit component of any one of Examples 31-33, wherein the first ferroelectric material and the second ferroelectric material are the same.

Example 35 comprises the integrated circuit component of any one of Examples 31-33, wherein the first ferroelectric material and the second ferroelectric material are perovskites.

Example 36 comprises the integrated circuit component of Example 35, wherein the first material and the second material are perovskites.

Example 37 comprises the integrated circuit component of any one of Examples 31-33, wherein the first ferroelectric material and the second ferroelectric material comprise lead, strontium, and titanium.

Example 38 comprises the integrated circuit component of Example 37, wherein the fourth layer comprises dysprosium, scandium, and oxygen.

Example 39 comprises the integrated circuit component of any one of Examples 31-33, wherein the first ferroelectric material and the second ferroelectric material comprise barium, titanium, and oxygen.

Example 40 comprises the integrated circuit component of any one of Examples 31-33, wherein the first ferroelectric material and the second ferroelectric material comprise bismuth, iron, and oxygen.

Example 41 comprises the integrated circuit component of Example 40, wherein the first ferroelectric material and/or the second ferroelectric material comprises samarium.

Example 42 comprises the integrated circuit component of Example 40, wherein the first ferroelectric material and/or the second ferroelectric material comprises lanthanum.

Example 43 comprises the integrated circuit component of any one of Examples 31-33, wherein the first ferroelectric material and the second ferroelectric material comprise lithium, tantalum, and oxygen.

Example 44 comprises the integrated circuit component of any one of Examples 31-33, wherein the first ferroelectric material and the second ferroelectric material comprise lead, zirconium, titanium, and oxygen.

Example 45 comprises the integrated circuit component of any one of Examples 31-33, wherein the first ferroelectric material and the second ferroelectric material comprise lead, niobium, zirconium, titanium, and oxygen.

Example 46 comprises the integrated circuit component of any one of Examples 31-33, wherein the first ferroelectric material and the second ferroelectric material comprise lead, lanthanum, zirconium, titanium, and oxygen.

Example 47 comprises the integrated circuit component of any one of Examples 31-33, wherein the first ferroelectric material and the second ferroelectric material comprise sodium, tantalum, and oxygen.

Example 48 comprises the integrated circuit component of any one of Examples 31-33, wherein the first ferroelectric material and the second ferroelectric material comprise strontium, titanium, and oxygen.

Example 49 comprises the integrated circuit component of any one of Examples 31-33, wherein the first ferroelectric material and the second ferroelectric material comprise potassium, tantalum, and oxygen.

Example 50 comprises the integrated circuit component of any one of Examples 31-33, wherein the first ferroelectric material and the second ferroelectric material comprise barium, strontium, titanium, and oxygen.

Example 51 comprises the integrated circuit component of any one of Examples 31-33, wherein the first ferroelectric material and the second ferroelectric material comprise tantalum and oxygen.

Example 52 comprises the integrated circuit component of any one of Examples 31-33, wherein the first ferroelectric material and the second ferroelectric material comprise bismuth, iron, cobalt, and oxygen.

Example 53 comprises the integrated circuit component of any one of Examples 31-33, wherein the first ferroelectric material and the second ferroelectric material comprise potassium, sodium, and oxygen.

Example 54 comprises the integrated circuit component of any one of Examples 31-33, wherein the first ferroelectric material and the second ferroelectric material comprise calcium, niobium, titanium, and oxygen.

Example 55 comprises the integrated circuit component of any one of Examples 31-33, wherein the first ferroelectric material and the second ferroelectric material comprise lead, bismuth, niobium, and oxygen.

Example 56 comprises the integrated circuit component of any one of Examples 31-33, wherein the first ferroelectric material and the second ferroelectric material comprise calcium, niobium, nitrogen, and oxygen.

Example 57 comprises the integrated circuit component of any one of Examples 31-33, wherein the first ferroelectric material and the second ferroelectric material comprise bismuth, titanium, and oxygen.

Example 58 comprises the integrated circuit component of any one of Examples 31-33, wherein the first ferroelectric material and the second ferroelectric material comprise barium, hafnium, titanium, and oxygen.

Example 59 comprises the integrated circuit component of any one of Examples 31-33, wherein the first ferroelectric material and the second ferroelectric material comprise barium, calcium, zirconium, titanium, and oxygen.

Example 60 comprises the integrated circuit component of any one of Examples 31-33, wherein the first ferroelectric material and the second ferroelectric material comprise gadolinium, iron, and oxygen.

Example 61 comprises the integrated circuit component of any one of Examples 31-33, wherein the first ferroelectric material and the second ferroelectric material comprise gadolinium, lanthanum, iron, and oxygen.

Example 62 comprises the integrated circuit component of any one of Examples 31-33, wherein the first ferroelectric material and the second ferroelectric material comprise tungsten and oxygen.

Example 63 comprises the integrated circuit component of any one of Examples 31-33, wherein the first ferroelectric material and the second ferroelectric material comprise barium, zirconium, titanium, and oxygen.

Example 64 comprises the integrated circuit component of any one of Examples 31-33, wherein the first ferroelectric material and the second ferroelectric material comprise barium, zirconium, titanium, and oxygen.

Example 65 comprises the integrated circuit component of any one of Examples 31-33, wherein the first ferroelectric material comprises: barium, titanium, and oxygen; bismuth, iron, and oxygen; bismuth, samarium, iron, and oxygen; bismuth, lanthanum, iron, and oxygen; lithium, tantalum, and oxygen; lithium, niobium, and oxygen; lead, strontium, and titanium; lead, zirconium, titanium, and oxygen; lead, niobium, zirconium, titanium, and oxygen; lead, lanthanum, zirconium, titanium, and oxygen; sodium, tantalum, and oxygen; strontium, titanium, and oxygen; potassium, tantalum, and oxygen; barium, strontium, titanium, and oxygen; tungsten and oxygen; bismuth, iron, cobalt, and oxygen; potassium, sodium, and oxygen; calcium, niobium, titanium, and oxygen; lead, bismuth, niobium, and oxygen; calcium, niobium, nitrogen, and oxygen; bismuth, titanium, and oxygen; barium, hafnium, titanium, and oxygen; barium, calcium, zirconium, titanium, and oxygen; gadolinium, iron, and oxygen; gadolinium, lanthanum, iron, and oxygen; tungsten and oxygen; barium, zirconium, titanium, and oxygen; or barium, zirconium, titanium, and oxygen; wherein the second ferroelectric material comprises: lead, strontium, and titanium; barium, titanium, and oxygen; bismuth, iron, and oxygen; bismuth, samarium, iron, and oxygen; bismuth, lanthanum, iron, and oxygen; lithium, tantalum, and oxygen; lithium, niobium, and oxygen; lead, strontium, and titanium; lead, zirconium, titanium, and oxygen; lead, niobium, zirconium, titanium, and oxygen; lead, lanthanum, zirconium, titanium, and oxygen; sodium, tantalum, and oxygen; strontium, titanium, and oxygen; potassium, tantalum, and oxygen; barium, strontium, titanium, and oxygen; tungsten and oxygen; bismuth, iron, cobalt, and oxygen; potassium, sodium, and oxygen; calcium, niobium, titanium, and oxygen; lead, bismuth, niobium, and oxygen; calcium, niobium, nitrogen, and oxygen; bismuth, titanium, and oxygen; barium, hafnium, titanium, and oxygen; barium, calcium, zirconium, titanium, and oxygen; gadolinium, iron, and oxygen; gadolinium, lanthanum, iron, and oxygen; tungsten and oxygen; barium, zirconium, titanium, and oxygen; or barium, zirconium, titanium, and oxygen.

Example 66 comprises the integrated circuit component of any one of Examples 31-33, wherein the first ferroelectric material comprises: lead, strontium, and titanium; lead, zirconium, titanium, and oxygen; lead, niobium, zirconium, titanium, and oxygen; or lead, lanthanum, zirconium, titanium, and oxygen; wherein the second ferroelectric material comprises: lead, strontium, and titanium; lead, zirconium, titanium, and oxygen; lead, niobium, zirconium, titanium, and oxygen; or lead, lanthanum, zirconium, titanium, and oxygen.

Example 67 comprises the integrated circuit component of any one of Examples 31-33, wherein the first ferroelectric material comprises: barium, titanium, and oxygen; bismuth, iron, and oxygen; bismuth, samarium, iron, and oxygen; bismuth, lanthanum, iron, and oxygen; lithium, tantalum, and oxygen; lithium, niobium, and oxygen; lead, strontium, and titanium; lead, zirconium, titanium, and oxygen; lead, niobium, zirconium, titanium, and oxygen; lead, lanthanum, zirconium, titanium, and oxygen; sodium, tantalum, and oxygen; strontium, titanium, and oxygen; potassium, tantalum, and oxygen; barium, strontium, titanium, and oxygen; bismuth, iron, cobalt, and oxygen; potassium, sodium, and oxygen; barium, hafnium, titanium, and oxygen; barium, calcium, zirconium, titanium, and oxygen; gadolinium, iron, and oxygen; gadolinium, lanthanum, iron, and oxygen; barium, zirconium, titanium, and oxygen; or barium, zirconium, titanium, and oxygen; wherein the second ferroelectric material comprises: barium, titanium, and oxygen; bismuth, iron, and oxygen; bismuth, samarium, iron, and oxygen; bismuth, lanthanum, iron, and oxygen; lithium, tantalum, and oxygen; lithium, niobium, and oxygen; lead, strontium, and titanium; lead, zirconium, titanium, and oxygen; lead, niobium, zirconium, titanium, and oxygen; lead, lanthanum, zirconium, titanium, and oxygen; sodium, tantalum, and oxygen; strontium, titanium, and oxygen; potassium, tantalum, and oxygen; barium, strontium, titanium, and oxygen; bismuth, iron, cobalt, and oxygen; potassium, sodium, and oxygen; barium, hafnium, titanium, and oxygen; barium, calcium, zirconium, titanium, and oxygen; gadolinium, iron, and oxygen; gadolinium, lanthanum, iron, and oxygen; barium, zirconium, titanium, and oxygen; or barium, zirconium, titanium, and oxygen.

Example 68 comprises the integrated circuit component of any one of Examples 31-33, wherein the first ferroelectric material comprises: calcium, niobium, titanium, and oxygen; lead, bismuth, niobium, and oxygen; calcium, niobium, nitrogen, and oxygen; or bismuth, titanium, and oxygen; wherein the second ferroelectric material comprises: calcium, niobium, titanium, and oxygen; lead, bismuth, niobium, and oxygen; calcium, niobium, nitrogen, and oxygen; or bismuth, titanium, and oxygen.

Example 69 comprises the integrated circuit component of any one of Examples 31-68, wherein the first ferroelectric material and the second ferroelectric material are the same except for the first ferroelectric material or the second ferroelectric material further comprising a dopant.

Example 70 comprises the integrated circuit component of any one of Examples 31-68, wherein the first ferroelectric material comprises a first dopant having a first concentration range in the first ferroelectric material, the second ferroelectric material comprises the first dopant having a second concentration range in the second ferroelectric material, a maximum concentration of the first concentration range is less than a minimum concentration of the second concentration range.

Example 71 comprises the integrated circuit component of any one of Examples 31-68, wherein the first ferroelectric material comprises a first dopant having a first concentration range in the first ferroelectric material, the second ferroelectric material comprises the first dopant having a second concentration range in the second ferroelectric material, the first concentration range substantially non-overlaps with the second concentration range.

Example 72 comprises the integrated circuit component of any one of Examples 31-68, wherein the first material or the second material comprises: strontium, ruthenium, and oxygen; strontium, barium, ruthenium, and oxygen; strontium, lanthanum, tin, and oxygen; lanthanum, strontium, manganese, and oxygen; lanthanum, barium, cobalt, and oxygen; lanthanum, niobium, and oxygen; lanthanum, ruthenium, and oxygen; strontium, vanadium, and oxygen; strontium, cobalt, and oxygen; strontium, molybdenum, and oxygen; or lanthanum, barium, tin, and oxygen.

Example 73 comprises the integrated circuit component of any one of Examples 31-68, wherein the first material or the second material comprises: yttrium, barium, copper, and oxygen; ruthenium and oxygen; iridium and oxygen; or molybdenum and oxygen.

Example 74 comprises the integrated circuit component of any one of Examples 31-68, wherein the first material or the second material comprises palladium, ruthenium, iridium, tungsten, platinum, or molybdenum.

Example 75 comprises the integrated circuit component of any one of Examples 31-68, wherein the first material or the second material comprises: barium, tin, and oxygen; barium, lanthanum, tin, and oxygen; barium, neodymium, tin, and oxygen; strontium, lanthanum, titanium, and oxygen; strontium, neodymium, titanium, and oxygen; indium, gallium, zinc, and oxygen; lanthanum, nickel, and oxygen; strontium, tin, and oxygen; or barium, strontium, tin, and oxygen.

Example 76 comprises the integrated circuit component of any one of Examples 31-68, wherein the first material or the second material comprises: strontium, titanium, and oxygen; or silicon and oxygen.

Example 77 is a method comprising: forming a first layer comprising a first material; forming a second layer on the first layer, the second layer comprising a first magnetoelectric material; forming a third layer on the second layer, the third layer comprising a second magnetoelectric material; and forming a fourth layer, the fourth layer comprising a second material, the third layer positioned between the second layer and the fourth layer.

Example 78 comprises the method of Example 77, further comprising: after forming the third layer, forming a fifth layer on the third layer, the fifth layer comprising the first magnetoelectric material; and after forming the fifth layer, forming a sixth layer on the fifth layer, the sixth layer comprising the second magnetoelectric material, the fifth layer and the sixth layer positioned between the third layer and the fourth layer.

Example 79 comprises the method of Example 78, wherein the first magnetoelectric material and the second magnetoelectric material are the same.

Example 80 comprises the method of any one of Examples 77-79, wherein the first magnetoelectric material and the second magnetoelectric material are perovskites.

Example 81 comprises the method of any one of Examples 77-79, wherein the first magnetoelectric material comprises: bismuth, iron, and oxygen; bismuth, iron, oxygen, and lanthanum; bismuth, iron, oxygen, and samarium; lutetium, iron, and oxygen; terbium, manganese, and oxygen; bismuth, titanium, and oxygen; lead, zirconium, titanium, and oxygen; lead, magnesium, niobium, oxygen, and titanium; chromium, oxygen; chromium, oxygen, and boron; boron and gallium; terbium, dysprosium, and iron; or iron, tellurium, and oxygen; wherein the second magnetoelectric material comprises: bismuth, iron, and oxygen; bismuth, iron, oxygen, and lanthanum; bismuth, iron, oxygen, and samarium; lutetium, iron, and oxygen; terbium, manganese, and oxygen; bismuth, titanium, and oxygen; lead, zirconium, titanium, and oxygen; lead, magnesium, niobium, oxygen, and titanium; chromium, oxygen; chromium, oxygen, and boron; boron and gallium; terbium, dysprosium, and iron; or iron, tellurium, and oxygen.

Example 82 comprises the method of any one of Examples 77-79, wherein the first magnetoelectric material comprises lead, zirconium, titanium, and oxygen; wherein the second magnetoelectric material comprises lead, magnesium, niobium, oxygen, and titanium.

Example 83 comprises the method of any one of Examples 77-79, wherein the first magnetoelectric material comprises: bismuth, iron, and oxygen; bismuth, iron, oxygen, and lanthanum; bismuth, iron, oxygen, and samarium; lutetium, iron, and oxygen; terbium, manganese, and oxygen; bismuth, titanium, and oxygen; lead, zirconium, titanium, and oxygen; lead, magnesium, niobium, titanium and oxygen; chromium, oxygen; or chromium, oxygen, and boron; wherein second third magnetoelectric material comprises: bismuth, iron, and oxygen; bismuth, iron, oxygen, and lanthanum; bismuth, iron, oxygen, and samarium; lutetium, iron, and oxygen; terbium, manganese, and oxygen; bismuth, titanium, and oxygen; lead, zirconium, titanium, and oxygen; lead, magnesium, niobium, titanium and oxygen; chromium, oxygen; or chromium, oxygen, and boron.

Example 84 comprises the method of any one of Examples 77-83, wherein the first magnetoelectric material and the second magnetoelectric material comprise the same except for the first magnetoelectric material or the second magnetoelectric material further comprising a dopant.

Example 85 comprises the method of any one of Examples 77-83, wherein the first magnetoelectric material comprises a first dopant having a first concentration range in the first magnetoelectric material, the second magnetoelectric material comprises the first dopant having a second concentration range in the second magnetoelectric material, a maximum concentration of the first concentration range is less than a minimum concentration of the second concentration range.

Example 86 comprises the method of any one of Examples 77-83, wherein the first magnetoelectric material comprises a first dopant having a first concentration range in the first magnetoelectric material, the second magnetoelectric material comprises the first dopant having a second concentration range in the second magnetoelectric material, the first concentration range substantially non-overlaps with the second concentration range.

Example 87 comprises the method of any one of Examples 77-86, wherein the first material or the second material comprises: cobalt and iron; cobalt, iron, and boron; nickel and iron; lanthanum, strontium, manganese, and oxygen; lanthanum, strontium, iron, molybdenum, and oxygen; or calcium, titanium, and oxygen.

Example 88 comprises the method of any one of Examples 77-86, wherein the first material or the second material comprises: lanthanum, strontium, manganese, and oxygen; niobium, strontium, titanium, and oxygen; or strontium, ruthenium, and oxygen.

Example 89 comprises the method of any one of Examples 77-86, wherein the first material comprises: cobalt and iron; cobalt, iron, and boron; or nickel and iron.

Example 90 comprises the method of any one of Examples 77-86, wherein the first material comprises bismuth, iron, and oxygen, and the second material comprises strontium, ruthenium, and oxygen.

Example 91 is a method for forming an integrated circuit component, the method comprising: forming a first layer comprising a first material; forming a second layer on the first layer, the second layer comprising a first ferroelectric material; forming a third layer on the second layer, the third layer comprising a second ferroelectric material; and forming a fourth layer, the fourth layer comprising a second material, the third layer positioned between the second layer and the fourth layer.

Example 92 comprises the method of Example 91, further comprising: after forming the third layer, forming a fifth layer on the third layer, the fifth layer comprising the first ferroelectric material; and after forming the fifth layer, forming a sixth layer on the fifth layer, the sixth layer comprising the second ferroelectric material, the fifth layer and the sixth layer positioned between the third layer and the fourth layer.

Example 93 comprises the method of Example 91, wherein a thickness of the second layer plus the third layer is about 10 nanometers or less.

Example 94 comprises the method of any one of Examples 91-93, wherein the first ferroelectric material and the second ferroelectric material are the same.

Example 95 comprises the method of any one of Examples 91-93, wherein the first ferroelectric material and the second ferroelectric material are perovskites.

Example 96 comprises the method of any one of Examples 91-93, wherein the first ferroelectric material comprises: barium, titanium, and oxygen; bismuth, iron, and oxygen; bismuth, samarium, iron, and oxygen; bismuth, lanthanum, iron, and oxygen; lithium, tantalum, and oxygen; lithium, niobium, and oxygen; lead, strontium, and titanium; lead, zirconium, titanium, and oxygen; lead, niobium, zirconium, titanium, and oxygen; lead, lanthanum, zirconium, titanium, and oxygen; sodium, tantalum, and oxygen; strontium, titanium, and oxygen; potassium, tantalum, and oxygen; barium, strontium, titanium, and oxygen; tungsten and oxygen; bismuth, iron, cobalt, and oxygen; potassium, sodium, and oxygen; calcium, niobium, titanium, and oxygen; lead, bismuth, niobium, and oxygen; calcium, niobium, nitrogen, and oxygen; bismuth, titanium, and oxygen; barium, hafnium, titanium, and oxygen; barium, calcium, zirconium, titanium, and oxygen; gadolinium, iron, and oxygen; gadolinium, lanthanum, iron, and oxygen; tungsten and oxygen; barium, zirconium, titanium, and oxygen; or barium, zirconium, titanium, and oxygen; wherein the second ferroelectric material comprises: lead, strontium, and titanium; barium, titanium, and oxygen; bismuth, iron, and oxygen; bismuth, samarium, iron, and oxygen; bismuth, lanthanum, iron, and oxygen; lithium, tantalum, and oxygen; lithium, niobium, and oxygen; lead, strontium, and titanium; lead, zirconium, titanium, and oxygen; lead, niobium, zirconium, titanium, and oxygen; lead, lanthanum, zirconium, titanium, and oxygen; sodium, tantalum, and oxygen; strontium, titanium, and oxygen; potassium, tantalum, and oxygen; barium, strontium, titanium, and oxygen; tungsten and oxygen; bismuth, iron, cobalt, and oxygen; potassium, sodium, and oxygen; calcium, niobium, titanium, and oxygen; lead, bismuth, niobium, and oxygen; calcium, niobium, nitrogen, and oxygen; bismuth, titanium, and oxygen; barium, hafnium, titanium, and oxygen; barium, calcium, zirconium, titanium, and oxygen; gadolinium, iron, and oxygen; gadolinium, lanthanum, iron, and oxygen; tungsten and oxygen; barium, zirconium, titanium, and oxygen; or barium, zirconium, titanium, and oxygen.

Example 97 comprises the method of any one of Examples 91-93, wherein the first ferroelectric material comprises: lead, strontium, and titanium; lead, zirconium, titanium, and oxygen; lead, niobium, zirconium, titanium, and oxygen; or lead, lanthanum, zirconium, titanium, and oxygen; wherein the second ferroelectric material comprises: lead, strontium, and titanium; lead, zirconium, titanium, and oxygen; lead, niobium, zirconium, titanium, and oxygen; or lead, lanthanum, zirconium, titanium, and oxygen.

Example 98 comprises the method of any one of Examples 91-93, wherein the first ferroelectric material comprises: barium, titanium, and oxygen; bismuth, iron, and oxygen; bismuth, samarium, iron, and oxygen; bismuth, lanthanum, iron, and oxygen; lithium, tantalum, and oxygen; lithium, niobium, and oxygen; lead, strontium, and titanium; lead, zirconium, titanium, and oxygen; lead, niobium, zirconium, titanium, and oxygen; lead, lanthanum, zirconium, titanium, and oxygen; sodium, tantalum, and oxygen; strontium, titanium, and oxygen; potassium, tantalum, and oxygen; barium, strontium, titanium, and oxygen; bismuth, iron, cobalt, and oxygen; potassium, sodium, and oxygen; barium, hafnium, titanium, and oxygen; barium, calcium, zirconium, titanium, and oxygen; gadolinium, iron, and oxygen; gadolinium, lanthanum, iron, and oxygen; barium, zirconium, titanium, and oxygen; or barium, zirconium, titanium, and oxygen; wherein the second ferroelectric material comprises: barium, titanium, and oxygen; bismuth, iron, and oxygen; bismuth, samarium, iron, and oxygen; bismuth, lanthanum, iron, and oxygen; lithium, tantalum, and oxygen; lithium, niobium, and oxygen; lead, strontium, and titanium; lead, zirconium, titanium, and oxygen; lead, niobium, zirconium, titanium, and oxygen; lead, lanthanum, zirconium, titanium, and oxygen; sodium, tantalum, and oxygen; strontium, titanium, and oxygen; potassium, tantalum, and oxygen; barium, strontium, titanium, and oxygen; bismuth, iron, cobalt, and oxygen; potassium, sodium, and oxygen; barium, hafnium, titanium, and oxygen; barium, calcium, zirconium, titanium, and oxygen; gadolinium, iron, and oxygen; gadolinium, lanthanum, iron, and oxygen; barium, zirconium, titanium, and oxygen; or barium, zirconium, titanium, and oxygen.

Example 99 comprises the method of any one of Examples 91-93, wherein the first ferroelectric material comprises: calcium, niobium, titanium, and oxygen; lead, bismuth, niobium, and oxygen; calcium, niobium, nitrogen, and oxygen; or bismuth, titanium, and oxygen; wherein the second ferroelectric material comprises: calcium, niobium, titanium, and oxygen; lead, bismuth, niobium, and oxygen; calcium, niobium, nitrogen, and oxygen; or bismuth, titanium, and oxygen.

Example 100 comprises the method of any one of Examples 91-96, wherein the first ferroelectric material comprises a first dopant having a first concentration range in the first ferroelectric material, the second ferroelectric material comprises the first dopant having a second concentration range in the second ferroelectric material, a maximum concentration of the first concentration range is less than a minimum concentration of the second concentration range.

Example 101 comprises the method of any one of Examples 91-96, wherein the first ferroelectric material comprises a first dopant having a first concentration range in the first ferroelectric material, the second ferroelectric material comprises the first dopant having a second concentration range in the second ferroelectric material, the first concentration range substantially non-overlaps with the second concentration range.

Example 102 comprises the method of any one of Examples 91-101, wherein the first material or the second material comprises: strontium, ruthenium, and oxygen; strontium, barium, ruthenium, and oxygen; strontium, lanthanum, tin, and oxygen; lanthanum, strontium, manganese, and oxygen; lanthanum, barium, cobalt, and oxygen; lanthanum, nickel, and oxygen; lanthanum, ruthenium, and oxygen; strontium, vanadium, and oxygen; strontium, cobalt, and oxygen; strontium, molybdenum, and oxygen; or lanthanum, barium, tin, and oxygen.

Example 103 comprises the method of any one of Examples 91-101, wherein the first material or the second material comprises: yttrium, barium, copper, and oxygen; ruthenium and oxygen; iridium and oxygen; or molybdenum and oxygen.

Example 104 comprises the method of any one of Examples 91-101, wherein the first material or the second material comprises palladium, ruthenium, or iridium.

Example 105 comprises the method of any one of Examples 91-101, wherein the first material or the second material comprises: barium, tin, and oxygen; barium, lanthanum, tin, and oxygen; barium, neodymium, tin, and oxygen; strontium, titanium, and oxygen; strontium, lanthanum, titanium, and oxygen; strontium, neodymium, titanium, and oxygen; indium, gallium, zinc, and oxygen; lanthanum, nickel, and oxygen; strontium, tin, and oxygen; or barium, strontium, tin, and oxygen.

Example 106 comprises the method of any one of Examples 91-101, wherein the first material or the second material comprises: strontium, titanium, and oxygen; or silicon and oxygen.

Example 107 comprises the method of any one of Examples 77-86 and 91-106, wherein the first material and the second material comprise a metal.

Example 108 comprises the method of any one of Examples 77-86 and 91-106, wherein the first material comprises a first metal and the second material comprises a second metal.

Example 109 comprises the integrated circuit component of any one of Examples 31-77, wherein the first material and the second material comprise a metal.

Example 110 comprises the integrated circuit component of any one of Examples 31-77, wherein the first material comprises a first metal and the second material comprises a second metal.

Example 111 comprises the integrated circuit component of any one of Examples 31-77, wherein the first material comprises: copper; aluminum, cobalt, tungsten, tantalum, nickel, molybdenum, or titanium and nickel; wherein the second material comprises: copper; aluminum, cobalt, tungsten, tantalum, nickel, molybdenum, or titanium and nickel.

Example 112 comprises the integrated circuit component of any one of Examples 31-77, wherein a coercive voltage of the second layer is less than a coercive voltage of the third layer.

Example 113 comprises the integrated circuit component of any one of Examples 31-77, wherein the integrated circuit component is a processor unit.

Example 114 comprises the integrated circuit component of any one of Examples 31-77, wherein the integrated circuit component is an integrated circuit component.

Example 115 comprises the integrated circuit component of Example 113 or 114, wherein the integrated circuit component further comprises one or more electronic transistors.

Example 116 comprises the integrated circuit component of any one of Examples 31-77, the integrated circuit component further comprising a spintronic device comprising the first layer, the second layer, the third layer, and the fourth layer.

Example 117 comprises the integrated circuit component of any one of Examples 31-77, wherein the first ferroelectric material is different from the second ferroelectric material.

1. An apparatus comprising:
a first layer comprising a first material;
a second layer comprising a first magnetoelectric material;
a third layer comprising a second magnetoelectric material, the second layer located on the third layer, the second layer located between the first layer and the third layer; and
a fourth layer comprising a second material, the third layer located between the second layer and the fourth layer.

2. The apparatus of claim 1, further comprising:
a fifth layer comprising the first magnetoelectric material, the third layer located on the fifth layer; and
a sixth layer comprising the second magnetoelectric material, the fifth layer located on the sixth layer, the fifth layer located between the third layer and the sixth layer, the sixth layer located between the fifth layer on the fourth layer.

3. The apparatus of claim 1,
wherein the first magnetoelectric material comprises:
bismuth, iron, and oxygen;
bismuth, iron, oxygen, and lanthanum;
bismuth, iron, oxygen, and samarium;
lutetium, iron, and oxygen;
terbium, manganese, and oxygen;
bismuth, titanium, and oxygen;
lead, zirconium, titanium, and oxygen;
lead, magnesium, niobium, titanium, and oxygen;
chromium, and oxygen;
chromium, oxygen, and boron;
boron and gallium;
terbium, dysprosium, and iron; or
iron, tellurium, and oxygen;
wherein the second magnetoelectric material comprises:
bismuth, iron, and oxygen;
bismuth, iron, oxygen, and lanthanum;
bismuth, iron, oxygen, and samarium;
lutetium, iron, and oxygen;
terbium, manganese, and oxygen;
bismuth, titanium, and oxygen;
lead, magnesium, niobium, titanium, and oxygen;
chromium, and oxygen;
chromium, and oxygen;
chromium, oxygen, and boron;
boron and gallium;
terbium, dysprosium, and iron; or
iron, tellurium, and oxygen.

4. The apparatus of claim 1, wherein the first magnetoelectric material comprises lead, zirconium, titanium, and oxygen; wherein the second magnetoelectric material comprises lead, magnesium, niobium, oxygen, and titanium.

5. The apparatus of claim 1,
wherein the first magnetoelectric material comprises:
bismuth, iron, and oxygen;
bismuth, iron, oxygen, and lanthanum;
bismuth, iron, oxygen, and samarium;
lutetium, iron, and oxygen;
terbium, manganese, and oxygen;
bismuth, titanium, and oxygen;
lead, magnesium, niobium, titanium, and oxygen;
chromium, and oxygen;
chromium, and oxygen; or
chromium, oxygen, and boron;
wherein the second magnetoelectric material comprises:
bismuth, iron, and oxygen;
bismuth, iron, oxygen, and lanthanum;
bismuth, iron, oxygen, and samarium;
lutetium, iron, and oxygen;
terbium, manganese, and oxygen;
bismuth, titanium, and oxygen;
lead, magnesium, niobium, titanium, and oxygen;
chromium, and oxygen;
chromium, and oxygen; or
chromium, oxygen, and boron.

6. The apparatus of claim 1, wherein the first magnetoelectric material and the second magnetoelectric material are the same except for the first magnetoelectric material or the second magnetoelectric material further comprising a dopant.

7. The apparatus of claim 1, wherein the first material or the second material comprises:
cobalt and iron;
cobalt, iron, and boron;
nickel and iron;
lanthanum, strontium, manganese, and oxygen;
lanthanum, strontium, iron, molybdenum, and oxygen;
calcium, titanium, and oxygen;
lanthanum, strontium, manganese, and oxygen;
niobium, strontium, titanium, and oxygen; or
strontium, ruthenium, and oxygen.

8. The apparatus of claim 1, wherein the first material comprises:
cobalt and iron;
cobalt, iron, and boron; or
nickel and iron.

9. The apparatus of claim 1, wherein the apparatus is an integrated circuit component.

10. An integrated circuit component comprising:
a first layer comprising a first material;
a second layer comprising a first ferroelectric material;
a third layer comprising a second ferroelectric material, the second layer located on the third layer, the second layer located between the first layer and the third layer, wherein the first ferroelectric material is different from the second ferroelectric material; and
a fourth layer comprising a second material, the third layer located between the second layer and the fourth layer.

11. The integrated circuit component of claim 10,
wherein the first ferroelectric material comprises:
lead, strontium, and titanium;
lead, zirconium, titanium, and oxygen;
lead, niobium, zirconium, titanium, and oxygen; or
lead, lanthanum, zirconium, titanium, and oxygen;
wherein the second ferroelectric material comprises:
lead, strontium, and titanium;
lead, zirconium, titanium, and oxygen;
lead, niobium, zirconium, titanium, and oxygen; or
lead, lanthanum, zirconium, titanium, and oxygen.

12. The integrated circuit component of claim 10,
wherein the first ferroelectric material comprises:
barium, titanium, and oxygen;
bismuth, iron, and oxygen;
bismuth, samarium, iron, and oxygen;
bismuth, lanthanum, iron, and oxygen;
lithium, tantalum, and oxygen;
lithium, niobium, and oxygen;
lead, strontium, and titanium;
lead, zirconium, titanium, and oxygen;
lead, niobium, zirconium, titanium, and oxygen;
lead, lanthanum, zirconium, titanium, and oxygen;
sodium, tantalum, and oxygen;
strontium, titanium, and oxygen;
potassium, tantalum, and oxygen;
barium, strontium, titanium, and oxygen;
bismuth, iron, cobalt, and oxygen;
potassium, sodium, and oxygen;
barium, hafnium, titanium, and oxygen;
barium, calcium, zirconium, titanium, and oxygen;
gadolinium, iron, and oxygen;
gadolinium, lanthanum, iron, and oxygen;
barium, zirconium, titanium, and oxygen; or
barium, zirconium, titanium, and oxygen;
wherein the second ferroelectric material comprises:
barium, titanium, and oxygen;
bismuth, iron, and oxygen;
bismuth, samarium, iron, and oxygen;
bismuth, lanthanum, iron, and oxygen;
lithium, tantalum, and oxygen;
lithium, niobium, and oxygen;
lead, strontium, and titanium;
lead, zirconium, titanium, and oxygen;
lead, niobium, zirconium, titanium, and oxygen;
lead, lanthanum, zirconium, titanium, and oxygen;
sodium, tantalum, and oxygen;
strontium, titanium, and oxygen;
potassium, tantalum, and oxygen;
barium, strontium, titanium, and oxygen;
bismuth, iron, cobalt, and oxygen;
potassium, sodium, and oxygen;
barium, hafnium, titanium, and oxygen;
barium, calcium, zirconium, titanium, and oxygen;
gadolinium, iron, and oxygen;
gadolinium, lanthanum, iron, and oxygen;
barium, zirconium, titanium, and oxygen; or
barium, zirconium, titanium, and oxygen.

13. The integrated circuit component of claim 10,
wherein the first ferroelectric material comprises:
calcium, niobium, titanium, and oxygen;
lead, bismuth, niobium, and oxygen;
calcium, niobium, nitrogen, and oxygen; or
bismuth, titanium, and oxygen;
wherein the second ferroelectric material comprises:
calcium, niobium, titanium, and oxygen;
lead, bismuth, niobium, and oxygen;
calcium, niobium, nitrogen, and oxygen; or
bismuth, titanium, and oxygen.

14. The integrated circuit component of claim 10, wherein the first material or the second material comprises:
strontium, ruthenium, and oxygen;
strontium, barium, ruthenium, and oxygen;
strontium, lanthanum, tin, and oxygen;
lanthanum, strontium, manganese, and oxygen;
lanthanum, barium, cobalt, and oxygen;
lanthanum, niobium, and oxygen;
lanthanum, ruthenium, and oxygen;
strontium, vanadium, and oxygen;
strontium, cobalt, and oxygen;
strontium, molybdenum, and oxygen; or
lanthanum, barium, tin, and oxygen.

15. The integrated circuit component of claim 10, wherein the first material or the second material comprises:
barium, tin, and oxygen;
barium, lanthanum, tin, and oxygen;
barium, neodymium, tin, and oxygen;
strontium, lanthanum, titanium, and oxygen;
strontium, neodymium, titanium, and oxygen;
indium, gallium, zinc, and oxygen;
lanthanum, nickel, and oxygen;
strontium, tin, and oxygen; or
barium, strontium, tin, and oxygen.

16. The integrated circuit component of claim 10, the integrated circuit component further comprising a spintronic device comprising the first layer, the second layer, the third layer, and the fourth layer.

17. A method comprising:
forming a first layer comprising a first material;
forming a second layer on the first layer, the second layer comprising a first magnetoelectric material;
forming a third layer on the second layer, the third layer comprising a second magnetoelectric material; and
forming a fourth layer, the fourth layer comprising a second material, the third layer positioned between the second layer and the fourth layer.

18. The method of claim 17,
wherein the first magnetoelectric material comprises:
bismuth, iron, and oxygen;
bismuth, iron, oxygen, and lanthanum;
bismuth, iron, oxygen, and samarium;
lutetium, iron, and oxygen;
terbium, manganese, and oxygen;
bismuth, titanium, and oxygen;
lead, zirconium, titanium, and oxygen;
lead, magnesium, niobium, oxygen, and titanium;
chromium, oxygen;
chromium, oxygen, and boron;
boron and gallium;
terbium, dysprosium, and iron; or
iron, tellurium, and oxygen;
wherein the second magnetoelectric material comprises:
bismuth, iron, and oxygen;
bismuth, iron, oxygen, and lanthanum;
bismuth, iron, oxygen, and samarium;
lutetium, iron, and oxygen;
terbium, manganese, and oxygen;
bismuth, titanium, and oxygen;
lead, zirconium, titanium, and oxygen;
lead, magnesium, niobium, oxygen, and titanium;
chromium, oxygen;
chromium, oxygen, and boron;
boron and gallium;
terbium, dysprosium, and iron; or
iron, tellurium, and oxygen.

19. The method of claim 17, wherein the first material or the second material comprises:
lanthanum, strontium, manganese, and oxygen;
niobium, strontium, titanium, and oxygen; or
strontium, ruthenium, and oxygen.

20. The method of claim 17, wherein the first material comprises:
cobalt and iron;
cobalt, iron, and boron; or
nickel and iron.
